(19) United States
(12) Patent Application Publication
(10) Pub. No.: US 2026/0323879 A1
(43) Pub. Date: Oct. 15, 2026

(54) PLUGGABLE ELECTRONIC MODULE WITH A RELEASE STRUCTURE

(71) Applicant: MELLANOX TECHNOLOGIES, LTD., Yokneam (IL)

(72) Inventors: Sagi Porat, Haifa (IL); Nimer Hazin, Ba'ne (IL); Jamal Mousa, Haifa (IL)

(21) Appl. No.: 19/248,328

(22) Filed: Jun. 24, 2025

Related U.S. Application Data
(60) Provisional application No. 63/786,567, filed on Apr. 10, 2025.

(51) Int. Cl. H05K 7/20

(52) U.S. Cl. CPC H05K 7/2039

(57) ABSTRACT

Examples of a pluggable electronic module are disclosed. In an example, a pluggable electronic module includes a housing having a front end and a back end, wherein the back end of the housing includes a sloped leading edge with a channel in a central region of the sloped leading edge. In an example, the channel is configured to reduce contact with a thermal interface material (TIM) during insertion of the pluggable electronic module into a cage. In an example, the channel is configured to reduce contact with a TIM at high-pressure points during insertion of the pluggable electronic module into a cage to reduce the risk of puncture and tearing of the TIM, wherein the TIM covers a portion of a heatsink. In an example, opposite sides of the channel are defined by rails that are elevated relative to a bottom surface of the channel.

### CROSS-REFERENCE TO RELATED APPLICATION

This application claims priority to provisional U.S. Patent Application Ser. No. 63/786,567, filed Apr. 10, 2025, which is incorporated by reference herein.

### FIELD

The present disclosure is generally directed to networking cable assemblies and relates more particularly to pluggable electronic modules, such as optical transceivers.

### BACKGROUND

Datacenters are the storage and data processing hubs of the Internet. Cable assemblies are used to interconnect network devices and/or network switches within a datacenter to enable high-speed communication between the network switches.

### GENERAL DESCRIPTION

Examples of a pluggable electronic module are disclosed. In an example, a pluggable electronic module includes a housing having a front end and a back end, wherein the back end of the housing includes a sloped leading edge with a channel in a central region of the sloped leading edge.

In an example, the channel is configured to reduce contact with a thermal interface material (TIM) during insertion of the pluggable electronic module into a cage.

In an example, the channel is configured to reduce contact with a TIM at high-pressure points during insertion of the pluggable electronic module into a cage to reduce the risk of puncture and tearing of the TIM, wherein the TIM covers a portion of a heatsink.

In an example, the channel is configured to reduce contact with a TIM at high-pressure points during insertion of the pluggable electronic module into a cage, and wherein rails of the housing act to resist a spring mechanism of a heatsink, ensuring that the heatsink aligns properly within a cage.

In an example, the channel is configured to reduce contact with a TIM during insertion of the pluggable electronic module into a cage, wherein the TIM covers a portion of a heatsink.

In an example, opposite sides of the channel are defined by rails that are elevated relative to a bottom surface of the channel.

In an example, the housing has a width dimension, and the channel has a width dimension that is in the range of 40-90% of the width dimension of the housing.

In an example, the sloped leading edge at the back end of the housing has a rounded shape.

In an example, the sloped leading edge is at a top side of the back end of the housing.

In an example, the channel has a slope that matches a slope of the sloped leading edge at the back end of the housing.

In an example, the sloped leading edge at the back end of the housing has a rounded shape, and wherein the channel has a rounded shape that matches a rounded shape of the sloped leading edge at the back end of the housing.

In an example, the channel runs parallel to a centerline of the housing.

In an example, the housing is an elongated structure, and wherein the channel runs parallel to a centerline of the elongated structure.

In an example, the pluggable electronic module includes a communications circuit within the housing, the communications circuit including a cable connector at the front end of the housing and a printed circuit board (PCB) interface at the back end of the housing.

In an example, the pluggable electronic module is an optical transceiver that includes a communications circuit within the housing, the communications circuit including a cable connector at the front end of the housing and a PCB interface at the back end of the housing.

Another example of a pluggable electronic module is disclosed. The pluggable electronic module includes a housing having a front end and a back end, a cable connector at the front end of the housing, and a sloped leading edge at the back end of the housing, wherein the sloped leading edge at the back end of the housing includes a channel in a central region of the sloped leading edge.

In an example, the channel is configured to reduce contact with a TIM during insertion of the pluggable electronic module into a cage.

In an example, The pluggable electronic module of claim 16, wherein the pluggable electronic module includes a communications circuit within the housing, the communications circuit including the cable connector at the front end of the housing and a PCB interface at the back end of the housing.

In an example, the pluggable electronic module includes a communications circuit within the housing, the communications circuit including the cable connector at the front end of the housing and a PCB interface at the back end of the housing, and the channel is configured to reduce contact with a TIM during insertion of the pluggable electronic module into a cage.

Another example of a pluggable electronic module is disclosed. The pluggable electronic module includes a housing having a front end and a back end, and a communications circuit within the housing, the communications circuit including a cable connector at the front end of the housing and a printed circuit board (PCB) interface at the back end of the housing, wherein the back end of the housing includes a sloped leading edge, wherein the sloped leading edge at the back end of the housing includes a channel in a central region of the sloped leading edge.

In an example, the channel is configured to reduce contact with a TIM during insertion of the pluggable electronic module into a cage.

In an example, opposite sides of the channel are defined by rails that are elevated relative to a bottom surface of the channel.

In an example, the housing has a width dimension, and the channel has a width dimension that is in the range of 40-90% of the width dimension of the housing.

Other aspects in accordance with the disclosure will become apparent from the following detailed description, taken in conjunction with the accompanying drawings, illustrated by way of example of the principles of the disclosure.

### BRIEF DESCRIPTION OF THE DRAWINGS

FIG. 1A is a perspective view of a cage for a pluggable electronic module.

FIG. 1B is a perspective view of the cage from FIG. 1A with a pluggable electronic module inserted in the cage and a riding heat sink connected to the cage.

FIG. 1C is a perspective view of a cage that includes a riding heat sink connected to the cage.

FIG. 2 is a top perspective view and a bottom perspective view of an example of a riding heat sink.

FIG. 3 is a view of the front end of a cage, which shows a thermal interface material within the cavity of the cage at an upper portion of the cage.

FIG. 4 is a perspective view of an example of a conventional pluggable electronic module that is configured for use with a riding heat sink.

FIG. 5 is a perspective view of an example of a pluggable electronic module that includes a sloped leading edge with a channel.

FIG. 6A is a top view of an example of a pluggable electronic module that includes a sloped leading edge at the back end with a channel.

FIG. 6B is a cross-sectional view of the pluggable electronic module from FIG. 6A.

FIG. 6C is a bottom view of the pluggable electronic module from FIG. 6A.

FIG. 6D is a top view of a portion of the pluggable electronic module from FIG. 6A.

FIG. 6E is a cross-sectional view of FIG. 6D.

FIG. 7 is a side view of a back end of the pluggable electronic module with a sloped leading edge.

FIG. 8 is a side cross-sectional view of a back end of the pluggable electronic module.

FIG. 9 is a perspective view of the back end of an example of a pluggable electronic module that includes a sloped leading edge with a channel.

FIG. 10 is a perspective view of the back end of another example of a pluggable electronic module that includes a sloped leading edge with a channel.

FIG. 11 is a perspective view of the back end of another example of a pluggable electronic module that includes a sloped leading edge with a channel in the housing.

FIG. 12 is a perspective view of the back end of another example of a pluggable electronic module that includes a sloped leading edge with a channel in the housing.

FIG. 13 is a top view of an example of a pluggable electronic module that includes a sloped leading edge at the back end with a channel relative to a cage and a thermal interface material.

FIG. 14 is a perspective view of a pluggable electronic module, a cage, and a riding heat sink that illustrates the pluggable electronic module being inserted into the cage.

FIG. 15 is a side view of an interaction between a portion of a riding heat sink and the sloped leading edge of the back end of the pluggable electronic module.

FIG. 16 is a front on view a heat sink and a pluggable electronic module with a channel in the sloped leading edge of the back end of the pluggable electronic module.

FIG. 17 is an example of different pluggable electronic modules that have leading edges with different shapes.

FIG. 18 illustrates a yaw angle between a cage and a pluggable electronic module.

FIG. 19 illustrates a pitch angle between a cage and a pluggable electronic module.

FIG. 20 illustrates an example of a computer system.

FIG. 21A is an example of a network architecture.

FIG. 21B is another example of a network architecture.

FIG. 22 is an example of a system that includes a device, a communications network, and a device.

FIG. 23 illustrates a fat tree topology for a datacenter.

FIG. 24 is an example of a fat tree topology of a network.

FIG. 25 illustrates an example data center.

FIGS. 26A and 26B illustrate a top view and a perspective view, respectively, of a transceiver module.

FIG. 27 depicts exemplary scenarios for use of an optical transceiver in accordance with some embodiments.

Throughout the description, similar reference numbers may be used to identify similar elements.

### DETAILED DESCRIPTION

It will be readily understood that the components of the examples as generally described herein and illustrated in the appended figures could be arranged and designed in a wide variety of different configurations. Thus, the following more detailed description of various examples, as represented in the figures, is not intended to limit the scope of the present disclosure, but is merely representative of various examples. While the various aspects of the examples are presented in drawings, the drawings are not necessarily drawn to scale unless specifically indicated.

The present disclosure may be embodied in other specific forms without departing from its spirit or essential characteristics. The described embodiments are to be considered in all respects only as illustrative and not restrictive. The scope of the disclosure is, therefore, indicated by the appended claims rather than by this detailed description. All changes which come within the meaning and range of equivalency of the claims are to be embraced within their scope.

Reference throughout this specification to features, advantages, or similar language does not imply that all of the features and advantages that may be realized with the present disclosure should be or are in any single example. Rather, language referring to the features and advantages is understood to mean that a specific feature, advantage, or characteristic described in connection with an example is included in at least one example of the present disclosure. Thus, discussions of the features and advantages, and similar language, throughout this specification may, but do not necessarily, refer to the same example.

Furthermore, the described features, advantages, and characteristics of the disclosure may be combined in any suitable manner in one or more embodiments. One skilled in the relevant art will recognize, in light of the description herein, that the disclosure can be practiced without one or more of the specific features or advantages of a particular embodiment. In other instances, additional features and advantages may be recognized in certain examples that may not be present in all examples of the disclosure.

Reference throughout this specification to “one example”, “an example”, or similar language means that a particular feature, structure, or characteristic described in connection with the indicated example is included in at least one embodiment of the present disclosure. Thus, the phrases “in one example”, “in an example”, and similar language throughout this specification may, but do not necessarily, all refer to the same embodiment.

In an example, the current disclosure addresses the issue of damage to a thermal interface material (TIM) during the insertion and extraction of an Octal Small Form Factor Pluggable (OSFP)-Riding Heat Sink (RHS) compatible pluggable electronic module into an OSFP-RHS compatible cage of a network port. In an example, the pluggable electronic module is on the switch side of a datacenter. When a pluggable electronic module is not inserted straight into an OSFP-RHS network port, several issues can arise that may lead to damage to the terminal interface material, the riding heat sink, and/or the pluggable electronic module. For example, inserting a pluggable electronic module at an angle (e.g., pitch angle and/or yaw angle) can cause uneven force distribution across the thermal interface material. The uneven force distribution can create high-pressure points that puncture or tear the protective TIM lamination layer of the thermal interface material. An uneven insertion angle can concentrate stress on specific areas of the thermal interface material, increasing the likelihood of damage. Angled insertion can generate shear forces that act parallel to the surface of the thermal interface material. The shear forces can cause delamination or tearing of the thermal interface material, especially if the pluggable electronic module is forced into the cage at a high pitch or yaw angle. Additionally, the shear forces can lead to abrasion of the thermal interface material and/or to the riding heat sink, further compromising the integrity of the thermal interface between the pluggable electronic module and the riding heat sink. In systems where multiple riding heat sinks are acted upon by a single spring, the spring force varies depending on the position of each heat sink. Angled insertion can exacerbate the variability in spring force, causing inconsistent pressure and increasing the risk of damage.

The OSFP multi-source agreement (MSA) specification defines the forces related to straight insertion, extraction, and retention of an OSFP module. As found in Table 9-1 of the OSFP MSA, the maximum insertion force for an OSFP module is 40N, or 55N if the cage has a riding heat sink. As described above, the high perpendicular force exerted by a riding heat sink can cause significant friction, especially if the pluggable electronic module is not inserted straight into the cage. When the pluggable electronic module is inserted into the cage at an angle, the uneven distribution of force can increase friction between the pluggable electronic module and the thermal interface material. The friction can lead to rapid wear and tear, puncturing, or tearing of the thermal interface material. In an example, the housing of a pluggable electronic module may be designed with various leading-edge shapes that are smooth and free of holes or grooves, providing smooth sliding conditions during insertion/extraction. For example, the leading edge may be sloped or rounded to provide smooth sliding conditions during insertion/extraction. The design of the housing of a pluggable electronic module addresses high-pressure points and shear forces that may be experienced by, for example, a lamination layer of the thermal interface material, under extreme mating conditions, reducing the risk of puncture and tearing. Contact between the housing of a pluggable electronic module and the riding heat sink in non-sensitive area helps resist the spring mechanism of the riding heat sink, ensuring that the riding heat sink aligns properly within the cage and reduces stress on the thermal interface material. While a sloped leading edge at the back end of a pluggable electronic module reduces the risk of damage to the thermal interface material, the sloped leading edge alone may not be entirely sufficient for extreme insertion angles. The rounded edges and sloped leading edge surface of the pluggable electronic module help, but they may not fully eliminate the risk of puncturing or tearing the thermal interface material under high-pressure points and shear forces.

To further mitigate the risk of damaging the thermal interface material, a release structure (e.g., a channel or indented section) is incorporated into a central region at the back end of the housing of a pluggable electronic module, where the pluggable electronic module interfaces with the heat sink. The configuration of the release structure (e.g., the channel) ensures that sensitive regions of the thermal interface material are protected from damaging stress during the insertion process. In an example, a channel in a central region of the sloped leading edge of a pluggable electronic module helps mitigate wear and tear, puncturing, or tearing of the thermal interface material by providing some space between the housing and the thermal interface material, thereby enabling smoother insertion and reducing stress on the sensitive areas of the thermal interface material by ensuring that the pressure is distributed along the edges. In an example, the central area at the back of the housing (e.g., also referred to as the backshell) is designed with a release structure (e.g., a channel) that prevents, minimizes, and/or reduces stress on the sensitive thermal interface material during insertion of the pluggable electronic module into a cage. For example, during insertion of a pluggable electronic module into a cage, the housing of the pluggable electronic module makes contact with a riding heat sink in non-sensitive areas, which helps resist the spring mechanism of the riding heat sink, ensuring smooth alignment. After an initial portion of the pluggable electronic module has been inserted into the cage, the housing of the pluggable electronic module aligns itself within the cage due to its smooth surface, reducing the risk of tearing the thermal interface material on the heatsink.

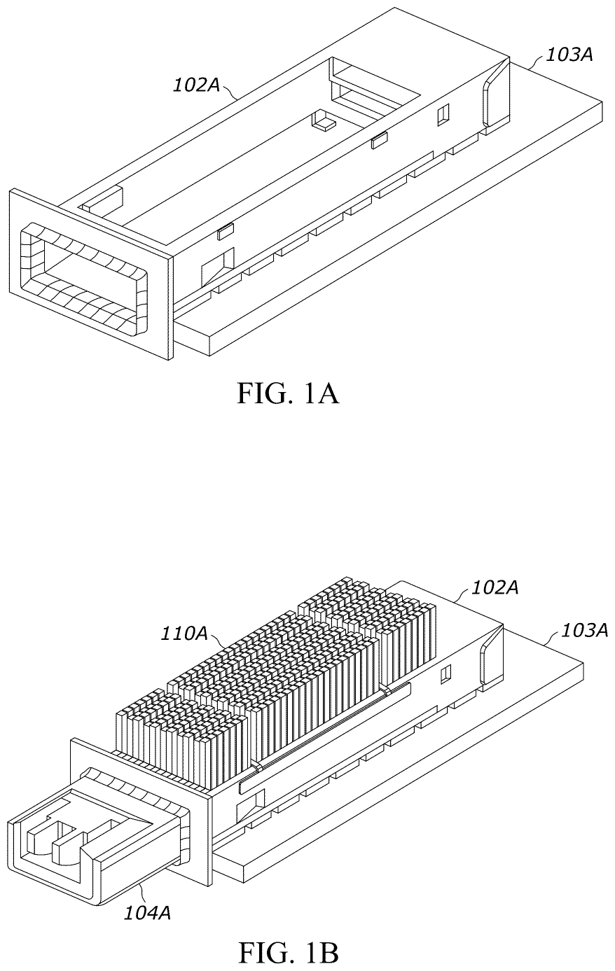

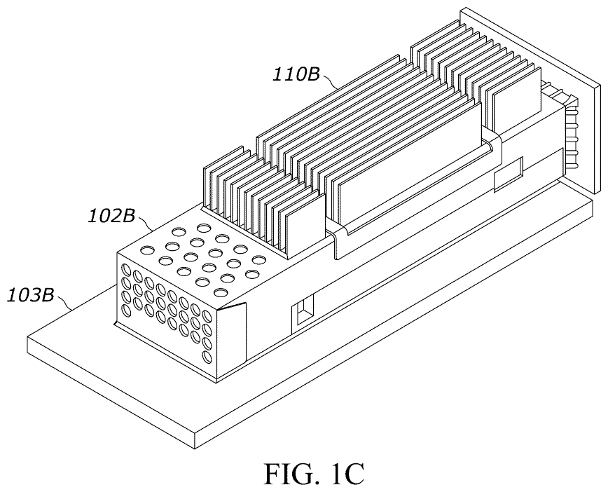

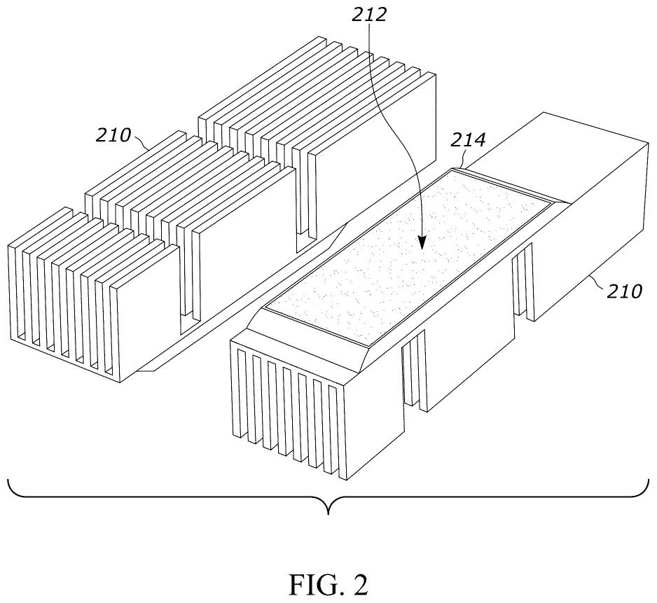

FIG. 1A is a perspective view of a cage 102A for a pluggable electronic module. The cage is attached to a substrate 103A such as a printed circuit board (PCB), and is configured to support use of a riding heat sink. In an example, the cage conforms to the OSFP specification.

FIG. 1B is a perspective view of the cage 102A from FIG. 1A with a pluggable electronic module 104A inserted in the cage and a riding heat sink 110A connected to the cage. In an example, the pluggable electronic module is an optical transceiver.

FIG. 1C is a perspective view of a cage 102B that includes a riding heat sink 110B connected to the cage. The cage 102B is attached to a substrate 103B, such as a PCB.

FIG. 2 is a top perspective view (left side) and a bottom perspective view (right side) of an example of a riding heat sink 210. The bottom perspective view of the riding heat sink shows a thermal interface material 212 on a surface of a pedestal 214 of the riding heat sink. In operation, the pedestal of the riding heat sink is positioned in the opening of a cage (e.g., as shown in FIG. 1A) and a force is applied to the riding heat sink to push the riding heat sink into the cavity of the cage to provide close contact between the pedestal of the riding heat sink and a top surface of a pluggable electronic module. In an example, the thermal interface material may be a phase change material (PCM) such as a Paraffin wax and the phase change material may be covered with a lamination layer such as a Kapton lamination layer. The phase change material is crucial for thermal conductivity. It helps transfer heat efficiently from the module to the heat sink, ensuring optimal performance. The release structure reduces friction and prevents the Kapton tape holding the phase change material from tearing, ensuring the phase change material remains intact and functional, thereby ensuring that the phase change material can effectively transfer heat without being damaged during insertion.

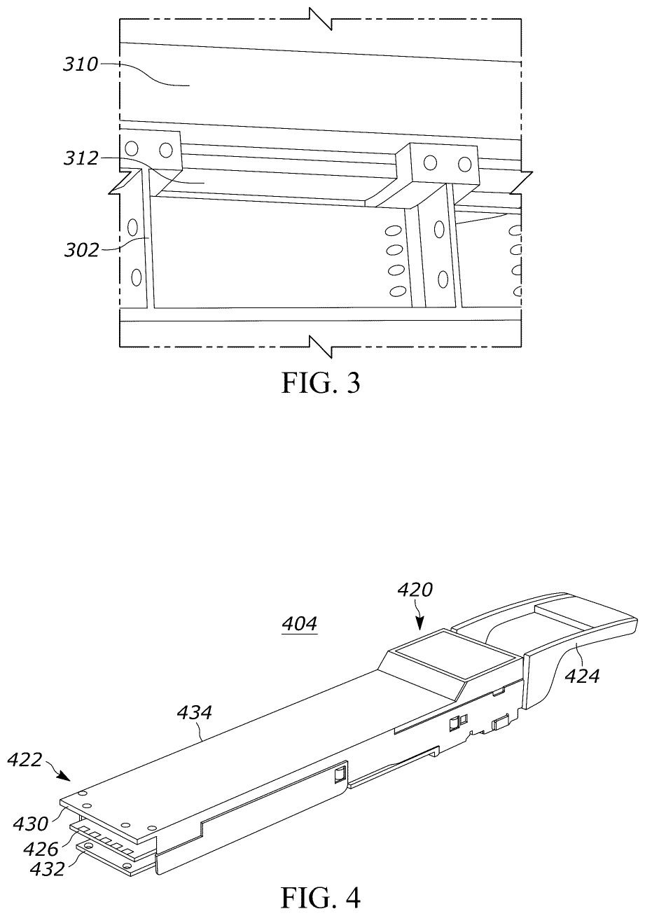

FIG. 3 is a view of the front end of a cage 302, which shows a thermal interface material 312 within a cavity formed by the cage at an upper portion of the cage. In the example, the thermal interface material is a phase change material that is affixed to a bottom surface of a pedestal of a riding heat sink 310 as described with reference to FIG. 2. In an example, the thermal interface material may include a phase change material that is covered with a lamination layer. Upon insertion of a pluggable electronic module into the cage, the thermal interface material is brought into close contact with a top surface of the pluggable electronic module to provide improved heat exchange between the pluggable electronic module and the riding heat sink.

FIG. 4 is a perspective view of an example of a conventional pluggable electronic module 404 that is configured for use with a riding heat sink. In the example of FIG. 4, the pluggable electronic module is an OSFP riding heat sink (OSFP-RHS) module as specified in the OSFP multi-source agreement (MSA). As described in the OSPF MSA, the pluggable electronic module has a front end 420 and a back end 422. The front end of the pluggable electronic module includes a cable connector (not visible) and a pull tab 424 and the back end of the pluggable electronic module includes a signal pad 426 (e.g., a PCB interface), an upper portion 430, and a lower portion 432 of a housing 434 of the pluggable electronic module. As shown in the example of FIG. 4, the leading edges of the upper and lower portions of the housing at the back end 422 of the pluggable electronic module protrude from the main body of the housing. In some cases, insertion of a conventional pluggable electronic module, such as the pluggable electronic module described with reference to FIG. 4, into a cage, such as the cage described with reference to FIG. 1A-1C and 3, can cause damage to the heat sink and/or to a thermal interface material that is attached to the heat sink and exposed at an upper portion of the cage (see FIG. 3). For example, protruding edges of the leading edge of the pluggable electronic module can damage the thermal interface material, particularly when the pluggable electronic module is inserted into the cage at an angle, e.g., a pitch angle and/or a yaw relative to the cage.

However, in accordance with an example of the current disclosure, a release structure (e.g., a channel) is incorporated into the central area at the back end of the backshell of a pluggable electronic module where the pluggable electronic module interfaces with a heat sink. The release structure (e.g., the channel) ensures that sensitive regions of the thermal interface material are protected from damaging stress during the insertion process. In an example, a pluggable electronic module includes a housing having a front end and a back end in which the back end of the housing includes a sloped leading edge with a channel in a central region of the sloped leading edge. The channel in the central region of the sloped leading edge of the housing is configured to reduce contact with a thermal interface material during insertion of the pluggable electronic module into a cage. Because the channel in the central region of the sloped leading edge reduces contact with the thermal interface material during insertion of the pluggable electronic module into the cage, the pluggable electronic module can be inserted into the cage without damaging the thermal interface material, which improves performance of the thermal interface material when brought into contact with the top surface of the pluggable electronic module and can extend the life of the system. The sloped leading edge and channel of the pluggable electronic module are especially effective in facilitating insertion of the pluggable electronic module at a pitch angle as is common in the field.

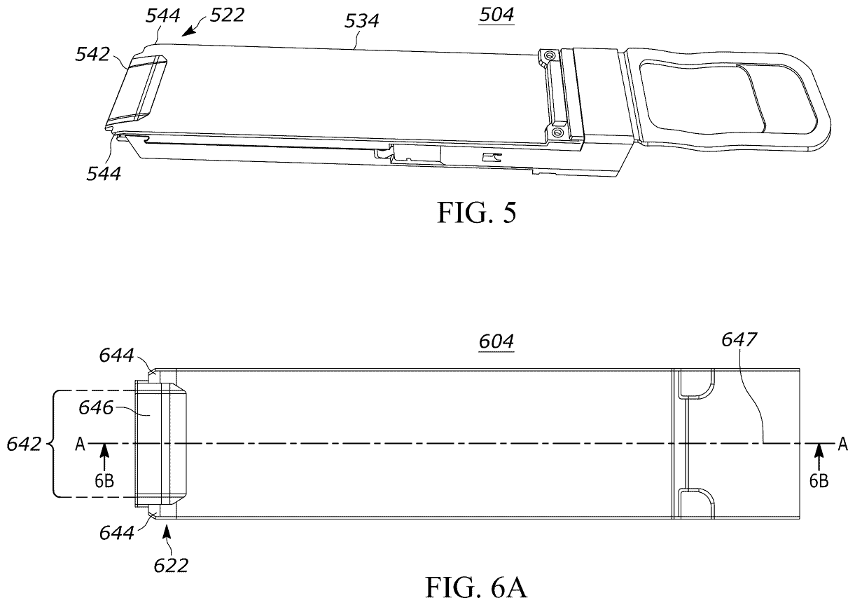

FIG. 5 is a perspective view of an example of a pluggable electronic module 504 that includes a sloped leading edge with a channel 542 in a central region of the sloped leading edge that is configured to reduce contact with a thermal interface material during insertion of the pluggable electronic module into a cage. In the example of FIG. 5, the sloped leading edge of the back end 522 of the housing 534 has an extended portion that is slightly narrower than the width of the pluggable electronic module and the channel spans nearly the entire width of the extended portion. The channel includes a bottom surface and opposite sides of the channel are defined by rails 544 that are elevated relative to the bottom surface of the channel. The rails serve to provide an upward force to the riding heat sink to resist spring loading of the riding heat sink. Thus, while being inserted into a cage, the rails of the pluggable electronic module move the riding heat sink upward within the cage and the channel provides room for the pluggable electronic module to enter the cage without gouging the thermal interface material.

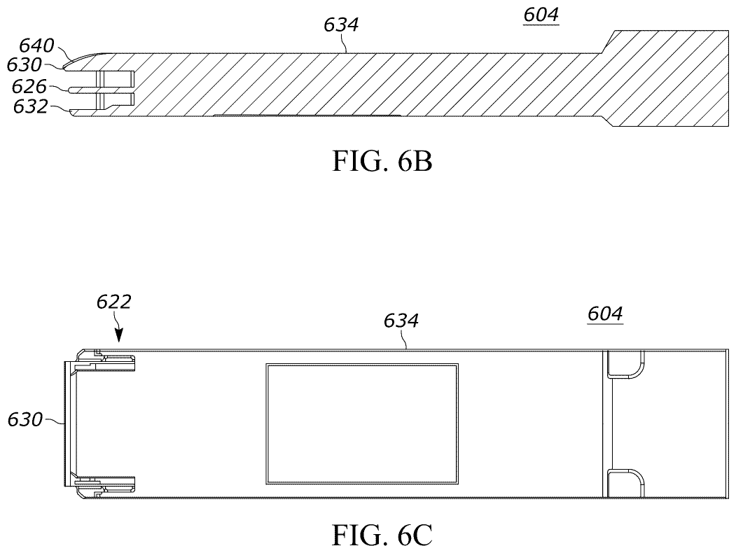

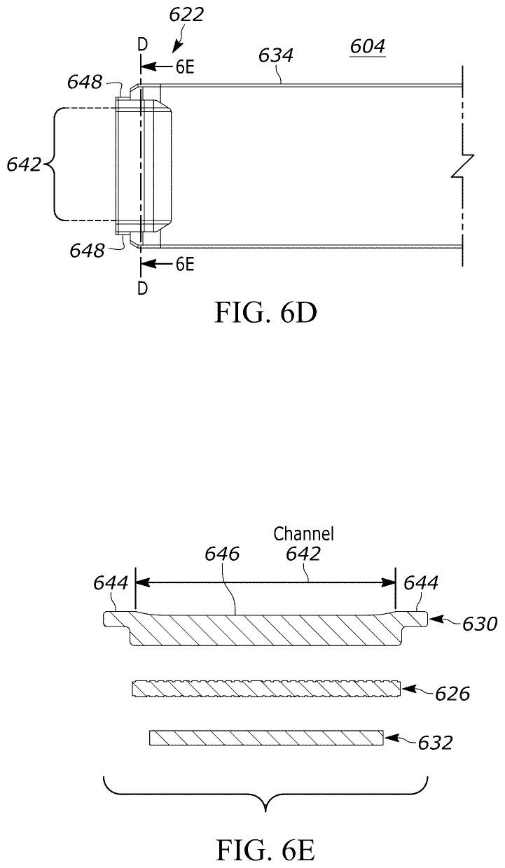

FIG. 6A is a top view of an example of a pluggable electronic module 604 that includes a sloped leading edge at the back end 622 with a channel 642 in a central region of the back end that is configured to reduce contact with a thermal interface material during insertion of the pluggable electronic module into a cage. As shown in FIG. 6A, the channel has a width that spans nearly the entire width of the extended portion of the housing. The channel includes a bottom surface and opposite sides of the channel are defined by two rails 644 that are elevated relative to the bottom surface of the channel. Opposite sides of the channel include the rails 644, which are elevated relative to the bottom surface 646 of the channel 642. The rails includes a small portion of the extended portion of the housing and a portion of the housing at the back end of the pluggable electronic module that is the full width of the pluggable electronic module. In an example, the central region of the sloped leading edge is a region of the sloped leading edge that is between the two elongated side edges of the pluggable electronic module and centered around a centerline 647 of the pluggable electronic module 604.

FIG. 6B is a cross-sectional view at cross-section AA of the pluggable electronic module from FIG. 6A. FIG. 6B shows a signal pad 626 (e.g., a PCB interface) and leading edges of upper and lower portions, 630 and 632 respectively, of the housing 634 of the pluggable electronic module. The leading edge of the upper portion of the housing is a sloped leading edge 640, which facilitates insertion of the pluggable electronic module at a pitch angle.

FIG. 6C is a bottom view of the pluggable electronic module 604 from FIG. 6A. As shown in FIG. 6C, the leading edge of the upper portion 630 at the back end 622 of the housing 634 includes an extended portion that is slightly narrower than the width of the pluggable electronic module. As shown in FIG. 5-6C, the pluggable electronic modules include an elongated housing with side dimensions that are multiple times larger than the width dimension and/or height dimension of the housing.

FIG. 6D is a top view of a portion of the pluggable electronic module 604 from FIG. 6A. FIG. 6D shows the width of the channel 642 relative to the width of the housing 634 and relative to the extended portion 648 of the leading edge of the back end 622. As shown in FIG. 6D, the width of the channel 642 is smaller than the width of the housing 634 and smaller than the width of the extended portion 648 of the leading edge of the back end 622.

FIG. 6E is a cross-sectional view at cross-section DD of FIG. 6D that shows the upper portion 630 of the housing (e.g., top leading edge), the PCB interface 626, and the lower portion 632 of the housing (e.g., bottom leading edge). Of note in FIG. 6E is the channel 642 at the top leading edge of the housing of the pluggable electronic module and the rails 644 at opposing edges of the channel. In the example of FIG. 6E, the bottom surface 646 of the channel is 15.05 mm wide, a distance between the top edges of the channel is 18.17 mm, the channel is about 0.21 mm deep, the entire housing is 22.58 mm wide, and each rail is about 1.94 mm wide, although other dimensions are possible. As described herein, during an early part of the insertion process, the rails 644 contact the riding heat sink and push upwards on the riding heat sink while the channel 642 provides enough clearance for the pluggable electronic module to pass by the thermal interface material on the pedestal of a riding heat sink without damaging the thermal interface material.

In an example, the channel has a slope that matches a slope of the sloped leading edge at the back end of the housing. In an example, the sloped leading edge at the back end of the housing has a rounded shape, and the channel has a rounded shape that matches a rounded shape of the sloped leading edge at the back end of the housing. In an example and as shown in FIG. 6A, the channel runs in a central region of the housing and parallel to the centerline 647 of the housing. In an example as shown in FIG. 6A, the housing is an elongated structure, and the channel runs parallel to the centerline of the elongated structure.

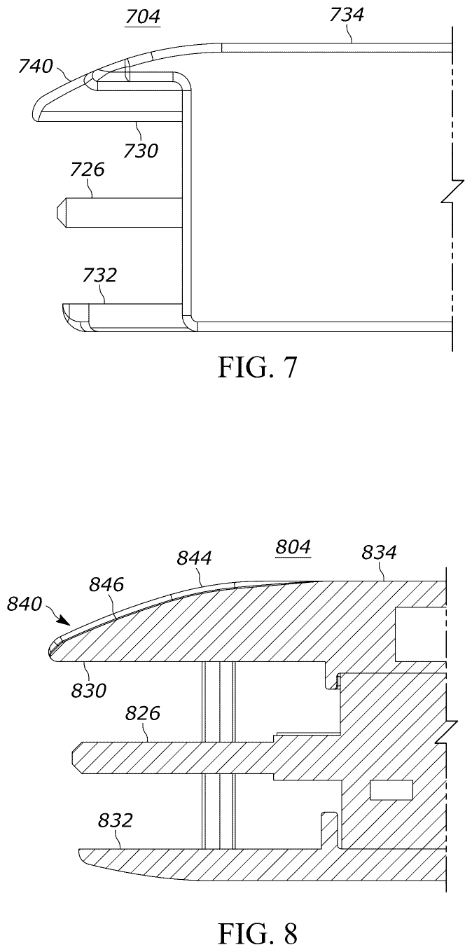

FIG. 7 is a side view of a back end of a pluggable electronic module 704 in which the top side of the housing 734 has a sloped leading edge 740. FIG. 7 shows a PCB interface 726 and leading edges of upper and lower portions, 730 and 732 respectively, of the housing 734 of the pluggable electronic module. The leading edge of the upper portion of the housing is a sloped leading edge, which facilitates insertion of the pluggable electronic module at a pitch angle. In an example, the sloped leading edge is a curved leading edge.

FIG. 8 is a side cross-sectional view of a back end of a pluggable electronic module 804 with a PCB interface 826 and leading edges of upper and lower portions, 830 and 832 respectively, of the housing 834 of the pluggable electronic module. The leading edge of the upper portion of the housing is a sloped leading edge 840, which facilitates insertion of the pluggable electronic module at a pitch angle. Additionally, FIG. 8 shows the bottom surface 846 of the channel and one rail 844 at the back end of the pluggable electronic module. In the example of FIG. 8, the difference in height between the bottom surface of the channel and the top of the rail is in the range of about 0.2-3 mm (e.g., ±10%). As described herein, the channel at the sloped leading edge of the pluggable electronic module provides some space for the back end of the pluggable electronic module to pass by the front edge of the thermal interface material while the pluggable electronic component is still at a pitch angle during an early portion of the insertion process.

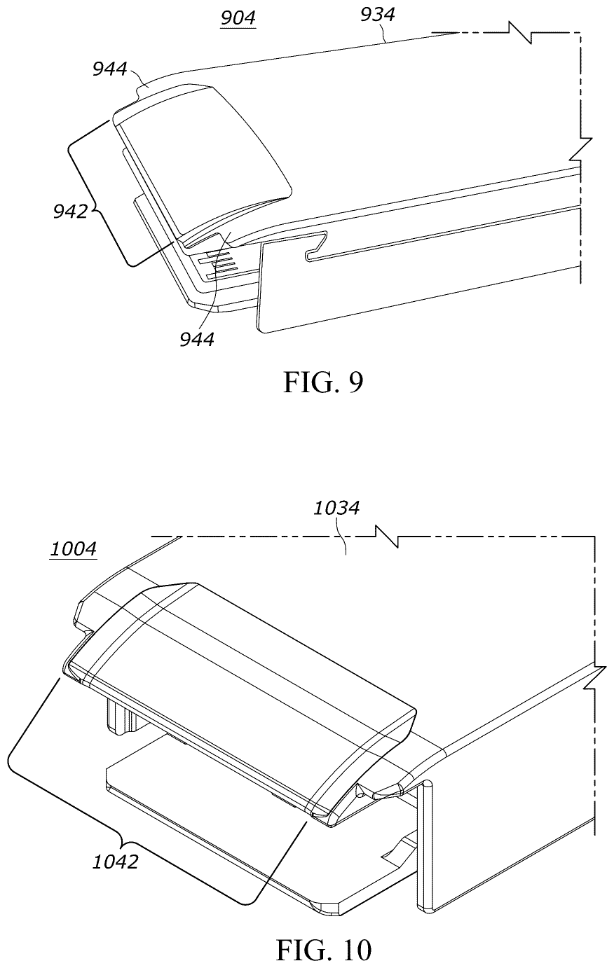

FIG. 9 is a perspective view of the back end of an example of a pluggable electronic module 904 that includes a sloped leading edge with a channel 942 in the housing 934 that is configured to reduce contact with a thermal interface material during insertion of the pluggable electronic module into a cage. As shown in FIG. 9, the boundaries of the bottom surface of the channel are defined by rails 944 that are on either side of the channel. The rails, which are elevated above the bottom surface of the channel, are the first portion of the leading edge to contact the riding heat sink and provide a force against spring loading that is applied to the riding heat sink. The rails force the riding heat sink to move upwards relative to the pluggable electronic module and the channel provides some clearance room for a thermal interface material to pass by the sloped leading edge of the back end so as to avoid damaging the thermal interface material during the early portion of the insertion process.

FIG. 10 is a perspective view of the back end of another example of a pluggable electronic module 1004 that includes a sloped leading edge with a channel 1042 in a central region of the housing 1034 that is configured to reduce contact with a thermal interface material during insertion of the pluggable electronic module into a cage. In the example of FIG. 10, the width of the pluggable electronic module is about 22.58 mm and the width of channel is about 16.25 mm (e.g., ±10%), which is about 72% of the total width of the pluggable electronic module. In the example of FIG. 10, the central region of the sloped leading edge is the region of the sloped leading edge that is between the two elongated side edges of the pluggable electronic module and centered around a centerline of the pluggable electronic module, such as the centerline 647 shown in FIG. 6A.

FIG. 11 is a perspective view of the back end of another example of a pluggable electronic module 1104 that includes a sloped leading edge with a channel 1142 in a central region of the housing 1134 that is configured to reduce contact with a thermal interface material during insertion of the pluggable electronic module into a cage. In the example of FIG. 11, the width of the pluggable electronic module is about 22.58 mm and the width of channel is about 10 mm (e.g., ±10%), which is about 44% of the total width of the pluggable electronic module. The width of the channel in the example of FIG. 11 is smaller than the width of the channel in the example of FIG. 10. As shown in FIGS. 10 and 11, the width of the channel may vary. For example, the width dimension of the channel be in the range of 40-90% of the width dimension of the housing. In an example, the width of the channel is slightly wider than the width of the thermal interface material on the pedestal of a riding heat sink so that there is adequate clearance for the pluggable electronic module to pass by the thermal interface material without damaging the thermal interface material. In the example of FIG. 11, the central region of the sloped leading edge is the region of the sloped leading edge that is between the two elongated side edges of the pluggable electronic module and centered around a centerline of the pluggable electronic module, such as the centerline 647 shown in FIG. 6A.

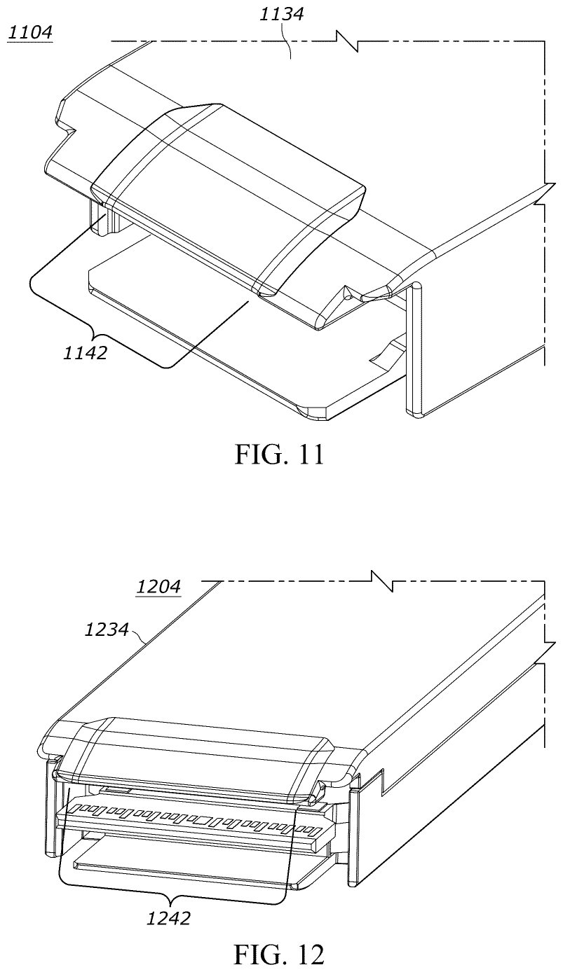

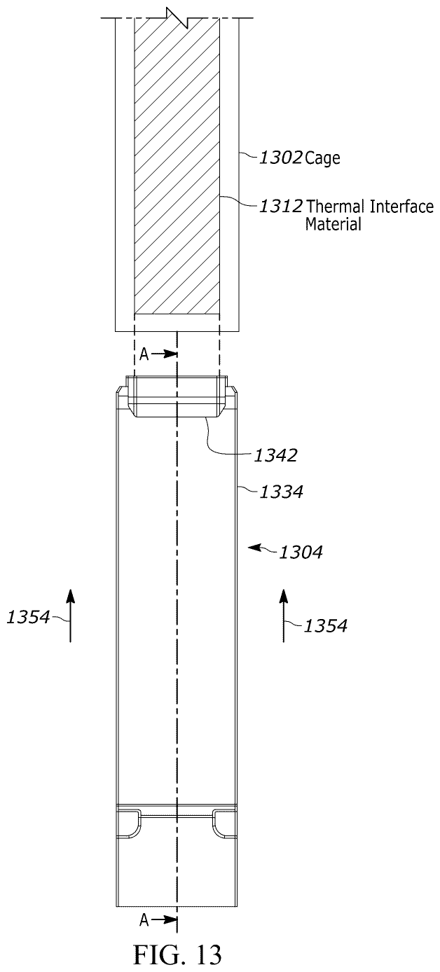

FIG. 12 is a perspective view of the back end of another example of a pluggable electronic module 1204 that includes a sloped leading edge with a channel 1242 in the housing 1234 that is configured to reduce contact with a thermal interface material during insertion of the pluggable electronic module into a cage.

FIG. 13 is a top view of an example of a pluggable electronic module 1304 that includes a sloped leading edge at the back end with a channel 1342 relative to a cage 1302 and a thermal interface material 1312 that is affixed to a riding heat sink (not shown). As described herein, the channel in the sloped back end of the housing 1334 of the pluggable electronic module is configured to reduce contact with the thermal interface material during insertion of the pluggable electronic module into the cage. In the example of FIG. 13, the channel 1342 in the central region of the sloped leading edge of the housing has a width that is slightly larger than the width of the thermal interface material 1312 on the pedestal of a riding heat sink so that there is adequate clearance for the pluggable electronic module to pass by the thermal interface material without damaging the thermal interface material. In operation, the pluggable electronic module 1304 is pushed into the cage 1302 in a direction as indicated by arrows 1354.

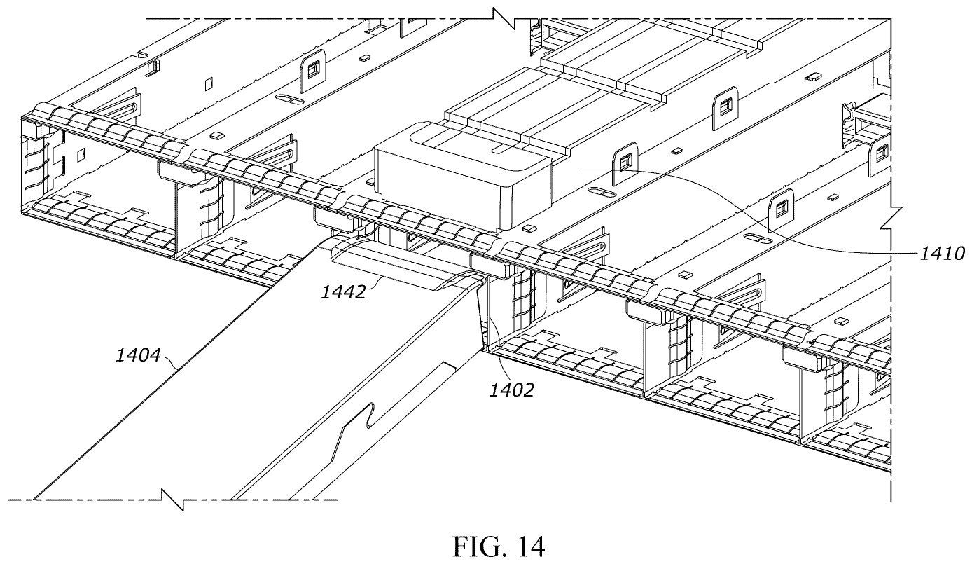

FIG. 14 is a perspective view of a pluggable electronic module 1404, a cage 1402, and a riding heat sink 1410 that illustrates the pluggable electronic module being inserted into the cage. As shown in FIG. 14, the pluggable electronic module may be inserted into the cage at a pitch angle. The channel 1442 in the sloped back end of the pluggable electronic module is configured to reduce contact with a thermal interface material that is on a pedestal of the riding heat sink during insertion of the pluggable module into the cage. In particular, the channel reduces or avoids contact between the leading edge of the pluggable electronic module during the beginning portion of the insertion process while the pluggable electronic module is still at an angle relative to the cage.

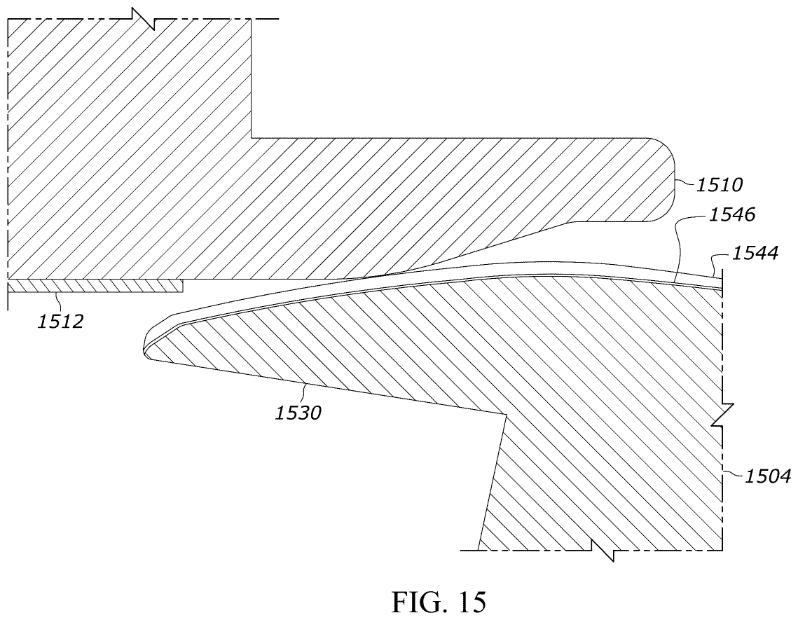

FIG. 15 is a side view cutaway of an interaction between a portion of a riding heat sink 1510 and the sloped leading edge of the upper portion 1530 of the pluggable electronic module 1504. FIG. 15 illustrates that the rail 1544 of the channel is in direct contact with the riding heat sink 1510 but the bottom surface 1546 of the channel is not in direct contact with the riding heat sink. FIG. 15 also shows that the channel has a slope that matches a slope of the sloped leading edge at the back end of the housing. Additionally, FIG. 15 shows a portion of the thermal interface material 1512 that is attached at the bottom of the riding heat sink. The channel at the sloped leading edge of the pluggable electronic module provides some space for the back end of the pluggable electronic module to pass by the front edge of the thermal interface material 1512 without damaging the thermal interface material while the pluggable electronic component is still at an angle during an early portion of the insertion process.

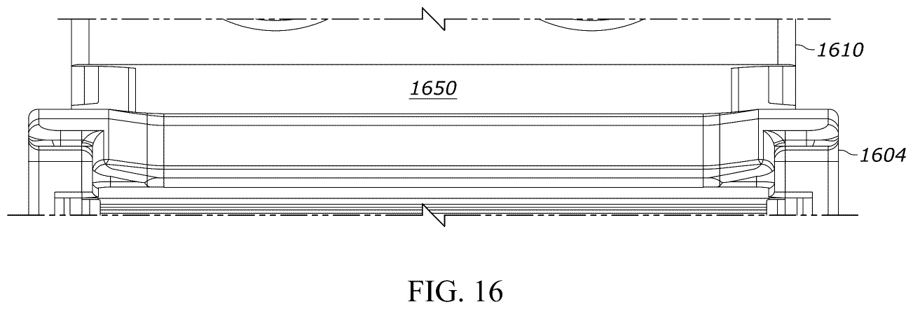

FIG. 16 is a front on view a heat sink 1610 and a pluggable electronic module 1604 with a channel in the sloped leading edge of the back end of the pluggable electronic module. The front view shows a gap 1650 that is exists between bottom surface of the channel and the riding heat sink.

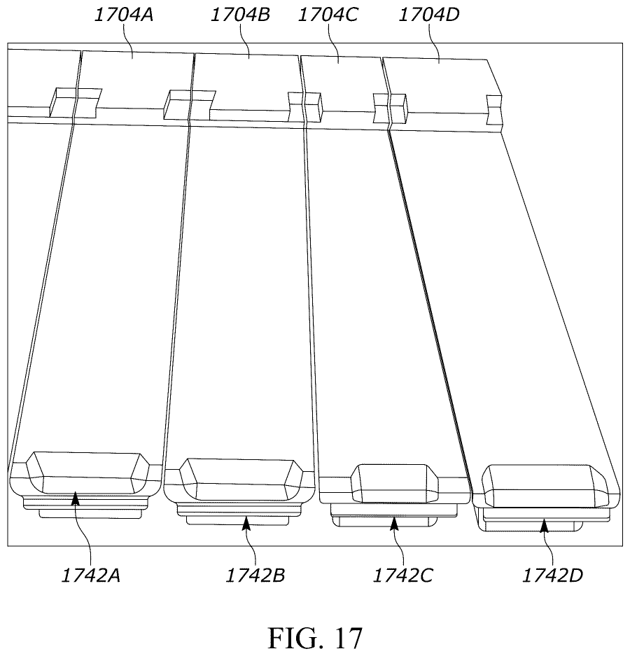

FIG. 17 is an example of different pluggable electronic modules that have leading edges with different shapes. For example, each release structure (e.g., channel or indenture) has a different size and/or shape. From the left to right, the pluggable electronic module 1704A has a release structure 1742A with a first shape, the pluggable electronic module 1704B has a release structure 1742B with a second shape, the pluggable electronic module 1704C has a release structure 1742C with a third shape, and the pluggable electronic module 1704D has a release structure 1742C with a fourth shape. In an example, the release structure 1742A includes two flat surfaces, each angled differently relative to the horizontal plane. The angles are variable depending on design and/or application requirements. In an example, the release structure 1742B includes two curved surfaces of variable radii. The curvature is not constant, which allows for a dynamic shape depending on the intended use. In an example, the release structure 1742D has an amorphous shape, which does not follow a defined linear or geometric shape. In an example, the release structure 1742C can share any combination of geometric profiles of release structures 1742A, 1742B, and 1742D, but in a smaller form factor, for example, a reduced width.

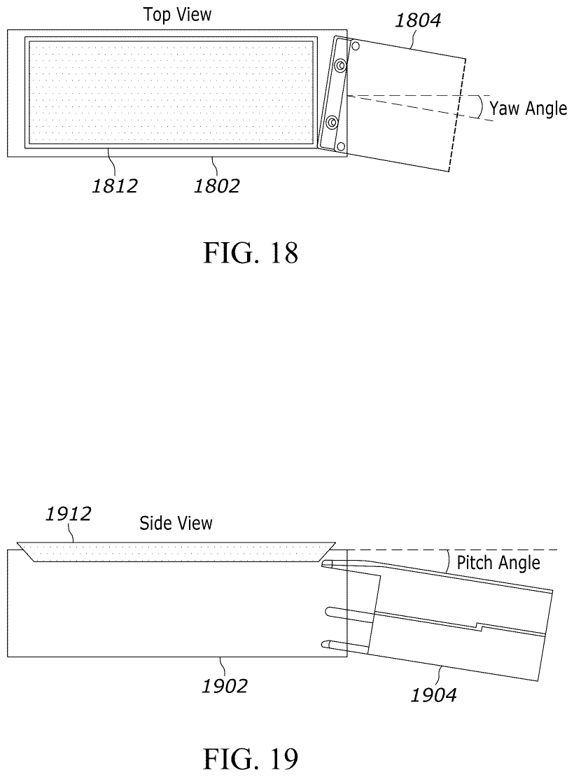

FIG. 18 illustrates a yaw angle between a cage 1802 and a pluggable electronic module 1804 relative to a phase change material 1812 as provided in a top view. As illustrated in FIG. 18, the pluggable electronic module may be inserted into the cage at a non-zero yaw angle, which may cause undesirable contact with the phase change material.

FIG. 19 illustrates a pitch angle between a cage 1902 and a pluggable electronic module 1904 relative to a phase change material 1912 as provided in a side view. As illustrated in FIG. 19, the pluggable electronic module may be inserted into the cage at a non-zero pitch angle, which may cause undesirable contact with the phase change material.

In an example, the pluggable electronic module with the sloped leading edge and channel in the central region is compatible with the OSFP MSA specification. In another example, the pluggable electronic module with the sloped leading edge and channel in the central region is compatible specifically with the OSFP-RHS specification. Additionally, although the examples are described with reference to an OSFP-RHS compatible pluggable electronic module, integrating a channel into the body of pluggable electronic module to prevent damage to a thermal interface material may be applicable to other form factors of pluggable electronic modules.

As described herein, to mitigate the risk of damage to the thermal interface material, a pluggable electronic module disclosed herein includes a channel (e.g., a release structure) in a central region at the back end of the housing. The channel ensures that the sensitive area of the thermal interface material does not experience damaging stress during insertion of the pluggable module into the cage. By including a channel in the back end and central area of the housing, the design allows for smoother insertion and reduces the risk of damage to the thermal interface material. The design of the pluggable electronic module as disclosed herein can significantly enhance the durability and performance of the corresponding system, ensuring the integrity of the thermal interface material even under extreme cable insertion angles.

In an example, the front end of a pluggable module or the front end of the housing of the pluggable electronic module is a portion of the pluggable electronic module or a portion of the hosing of the pluggable electronic module that is at or near a front edge of the pluggable electronic module or at or near a front edge of the housing (e.g., within about 20% of the total length of pluggable electronic module from the front edge) and the back end of a pluggable module or the back end of the housing of the pluggable electronic module is a portion of the pluggable electronic module or a portion of the hosing of the pluggable electronic module that is at or near a back edge of the pluggable electronic module or at or near a back edge of the housing (e.g., within about 20% of the total length of pluggable electronic module from the back edge).

As is known in the field, the pluggable electronic modules described herein may be a communications interface such as an optical transceiver that provides an interconnect between a communications media such as an optical fiber or twisted pair wires, and computer system such as a host computer. For example, a pluggable electronic module includes a communications circuit within the housing, a cable connector at the front end of the housing, which is coupled to the communications circuit, and a printed circuit board (PCB) interface at the back end of the housing, which is also coupled to the communications circuit. In an example operation, the pluggable electronic module is inserted into a cage, wherein the PCB interface is coupled to a complementary interface in the cage and the cable connector is coupled to an optical fiber. The communications circuit provides coupling of digital data between the cable connector and the PCB interface. As used herein, the interconnect features may be conductive portions of circuit board. For instance, the interconnect features may include metal traces, plated and non-plated through-holes, solder points, transmission lines, and electrically-insulating circuit board material over which such copper traces and solder points may lie. An interconnect feature may pass along sides and across the circuit board to contact between computing features, such as a chip to chip interconnect, an NVlink® interconnect, a PCIe® high speed communication interconnect, among other interconnects that may exist on a circuit board.

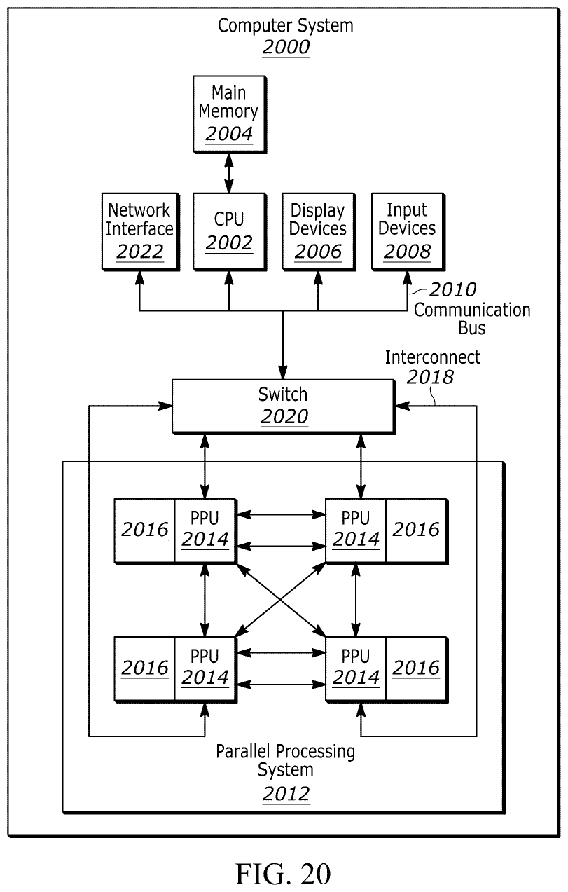

FIG. 20 illustrates a computer system 2000, according to at least one embodiment. In at least one embodiment, computer system 2000 is configured to implement various processes and methods described throughout this disclosure.

In at least one embodiment, computer system 2000 comprises, without limitation, at least one central processing unit (“CPU”) 2002 that is connected to a communication bus 2010 implemented using any suitable protocol, such as PCI (“Peripheral Component Interconnect”), peripheral component interconnect express (“PCI-Express”), AGP (“Accelerated Graphics Port”), HyperTransport, or any other bus or point-to-point communication protocol(s). In at least one embodiment, computer system 2000 includes, without limitation, a main memory 2004 and control logic (e.g., implemented as hardware, software, or a combination thereof) and data are stored in main memory 2004 which may take form of random access memory (“RAM”). In at least one embodiment, a network interface subsystem (“network interface”) 2022 provides an interface to other computing devices and networks for receiving data from and transmitting data to other systems from computer system 2000.

In at least one embodiment, computer system 2000, in at least one embodiment, includes, without limitation, input devices 2008, parallel processing system 2012, and display devices 2006 which can be implemented using a conventional cathode ray tube (“CRT”), liquid crystal display (“LCD”), light emitting diode (“LED”), plasma display, or other suitable display technologies. In at least one embodiment, user input is received from input devices 2008 such as keyboard, mouse, touchpad, microphone, and more. In at least one embodiment, each of foregoing modules can be situated on a single semiconductor platform to form a processing system.

In at least one embodiment, computer programs in form of machine-readable executable code or computer control logic algorithms are stored in main memory 2004 and/or secondary storage. Computer programs, if executed by one or more processors, enable system 2000 to perform various functions in accordance with at least one embodiment. memory 2004, storage, and/or any other storage are possible examples of computer-readable media. In at least one embodiment, secondary storage may refer to any suitable storage device or system such as a hard disk drive and/or a removable storage drive, representing a floppy disk drive, a magnetic tape drive, a compact disk drive, digital versatile disk (“DVD”) drive, recording device, universal serial bus (“USB”) flash memory, etc. In at least one embodiment, architecture and/or functionality of various previous figures are implemented in context of CPU 2002; parallel processing system 2012; an integrated circuit capable of at least a portion of capabilities of both CPU 2002; parallel processing system 2012; a chipset (e.g., a group of integrated circuits designed to work and sold as a unit for performing related functions, etc.); and any suitable combination of integrated circuit(s).

In at least one embodiment, architecture and/or functionality of various previous figures are implemented in context of a general computer system, a circuit board system, a game console system dedicated for entertainment purposes, an application-specific system, and more. In at least one embodiment, computer system 2000 may take form of a desktop computer, a laptop computer, a tablet computer, servers, supercomputers, a smart-phone (e.g., a wireless, hand-held device), personal digital assistant (“PDA”), a digital camera, a vehicle, a head mounted display, a hand-held electronic device, a mobile phone device, a television, workstation, game consoles, embedded system, and/or any other type of logic.

In at least one embodiment, parallel processing system 2012 includes, without limitation, a plurality of parallel processing units (“PPUs”) 2014 and associated memories 2016. In at least one embodiment, PPUs 2014 are connected to a host processor or other peripheral devices via an interconnect 2018 and a switch 2020 or multiplexer. In at least one embodiment, parallel processing system 2012 distributes computational tasks across PPUs 2014 which can be parallelizable, for example, as part of distribution of computational tasks across multiple graphics processing unit (“GPU”) thread blocks. In at least one embodiment, memory is shared and accessible (e.g., for read and/or write access) across some or all of PPUs 2014, although such shared memory may incur performance penalties relative to use of local memory and registers resident to a PPU 2014. In at least one embodiment, operation of PPUs 2014 is synchronized through use of a command such as_syncthreads( ), wherein all threads in a block (e.g., executed across multiple PPUs 2014) to reach a certain point of execution of code before proceeding.

Datacenters and other networking systems may include connections between datacenters, switch systems, servers, racks, and devices in order to provide for signal transmission between one or more of these elements. These connections may be made using cables, transceivers, interconnects, interposers, and connector assemblies. For high bandwidth applications and/or connections over long distances, high powered optical communications may be preferred to ensure signal transmission integrity.

Datacenters may include multiple network switches in a particular topology, such as a fat tree topology, a slim fly topology, a dragonfly topology, multi-level fat-trees, fat-flys, Benes, Clos, meshes, and tori and/or the like. The specifications and makeup of the network switches in the topology affects the overall network performance (e.g., bandwidth capability) of the datacenter.

Datacenters are the storage and data processing hubs of the internet. The massive deployment of cloud applications is causing datacenters to expand exponentially in size, stimulating the development of faster switches than can cope with the increasing data traffic inside the datacenter. Current state-of-the-art switches are capable of handling 12.8 Tb/s of traffic by employing electrical switches in the form of application specific integrated circuits (ASICs) equipped with 256 data lanes, each operating at 50 Gb/s. Such switching ASICs typically consume as much as 400 W, and the power consumption of the optical transceiver interfaces attached to each ASIC is comparable. To keep pace with traffic demand, switch capacity doubles approximately every two years. To date, this rapid scaling has been made possible by exploiting advances in manufacturing (e.g., CMOS techniques), collectively described by Moore's law (i.e., the observation that the number of transistors in a dense integrated circuit doubles about every two years). However, in recent years there are strong indications of Moore's law slowing down, which raises concerns about the capability to sustain the target scaling rate of switch capacity. As a result, alternative technologies are being investigated.

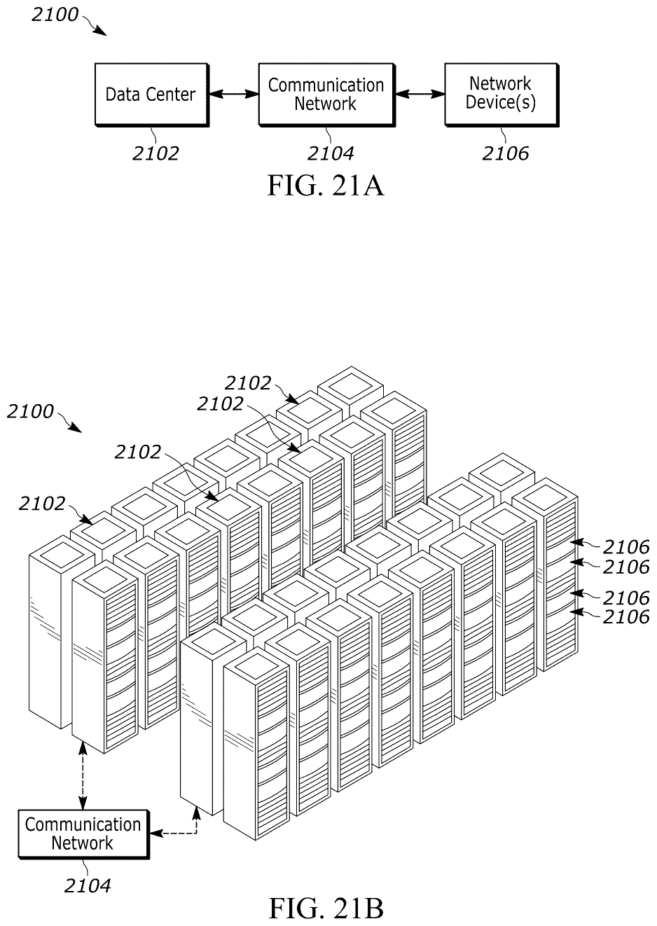

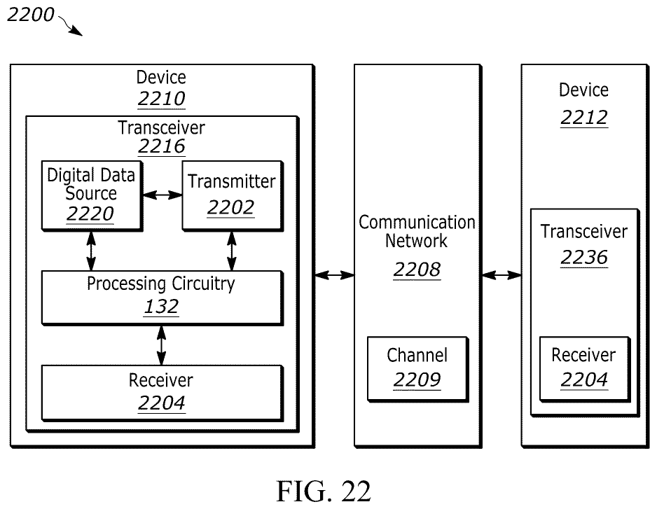

As described above, datacenters, high performance computing clusters, and/or the like are often formed of various computing components or networked devices, and communication networks formed of electrical and/or optical devices may be used to enable communication between the networked devices forming these implementations. With reference to FIGS. 21A-21B, for example, a network architecture 2100 may include a datacenter 2102, a communication network 2104, and network device(s) 2106. The network architecture 2100 may illustrate a general computing architecture within which more specific systems and/or subsystems may function. Although described hereinafter with reference to a network architecture 2100 and/or datacenter 2102 within which the embodiments of the present disclosure may be implemented, the present disclosure contemplates that the transceiver resiliency devices and techniques described herein may be applicable to any communication implementation without limitation.

For example, the datacenter 2102 may be a centralized facility designed to house computing resources and related components. The datacenter 2102 may operate to support the infrastructure required for advanced computational tasks, for efficient, secure, and reliable operations. The datacenter 2102 may include the building and structural components, including power supplies, cooling systems, fire suppression systems, and physical security measures that are configured to maintain optimal operating conditions and/or protect the equipment from environmental hazards and unauthorized access. An example datacenter 2102 may include high-performance servers or compute nodes, often arranged in racks, such as those illustrated in FIG. 21B, and connected through high-speed networks as described herein. These servers may include processors (e.g., central processing units (CPUs), graphics processing units (GPUs), data processing units (DPUs) and/or the like), memory (e.g., RAM), and storage solutions (e.g., hard disk drives (HDDs), solid state drives (SSDs), and/or the like. The hardware configuration may be designed for parallel processing and high throughput, catering to the demands of high-performance computing (HPC) applications.

The datacenter 2102 may include high-speed network equipment, such as network switches, routers, firewalls, and/or the like to facilitate fast and secure data transmission within the datacenter 2102 (e.g., between the servers or compute nodes) and between external networks. The datacenter 2102 may facilitate communication between servers or compute nodes through a network topology that ensures efficient data exchange, minimizes latency, and maximizes bandwidth. The network topology may dictate how various network devices, such as switches and routers, are interconnected for data flow. By implementing an effective network topology, the datacenter 2102 may support high-performance computing tasks. Examples of various network topologies may include hierarchical networking topologies such as the fat tree topology, Slim Fly topology, Dragonfly topology, and/or the like.

The communication network 2104 may communicably couple the datacenter 2102 with network device(s) 2106 and other external devices for data exchange and connectivity. Examples of the communication network 2104 may include an Internet Protocol (IP) network, an Ethernet network, an InfiniBand (IB) network, a Fibre Channel network, the Internet, a cellular communication network, a wireless communication network, combinations thereof (e.g., Fibre Channel over Ethernet), variants thereof, and/or the like. The ability of the communication network 2104 to incorporate multiple network types and configurations may allow the datacenter 2102 to adapt to diverse application needs, from general data communication to specialized HPC tasks. As described herein, the communication network 2104 may leverage various optical components to establish communication links (e.g., communicably couple) between components in the architecture 2100. As such, the communication network 2104 may include various optical devices, transceivers, modules, and/or the like that are configured to generate optical signals (e.g., provide optical transmitter functionality) and/or receive optical signals (e.g., provide optical receiver functionality).

The network device(s) 2106 may include a variety of computing devices capable of transmitting and receiving signals over the communication network 2104. The network device(s) 2106 may range from personal computing devices to complex server configurations. Examples include Personal Computers (PCs), laptops, tablets, smartphones, and servers. The network device(s) 2106 may facilitate user interactions with the datacenter 2102, allowing for data input, retrieval, and processing from remote locations. In addition to individual computing devices, the network device(s) 2106 may also include collections of servers or additional datacenters. For instance, these could be other datacenters similar to or the same as datacenter 2102. Such an interconnection may allow for the formation of a distributed computing environment for improved redundancy, load balancing, and disaster recovery capabilities. By linking multiple datacenters, the network architecture 2100 may leverage geographically dispersed resources, optimizing performance and ensuring high availability.

As described herein, the datacenter 2102 and/or the network device(s) 2106 may include storage devices and processing circuitry for executing computing tasks, such as controlling the flow of data internally and over the communication network 2104. The processing circuitry may include software, hardware, or a combination thereof. For example, the processing circuitry may include a memory containing executable instructions and a processor (e.g., a microprocessor) that executes these instructions. The memory may correspond to any suitable type of memory device or collection of memory devices configured to store instructions. Non-limiting examples of suitable memory devices include Flash memory, Random Access Memory (RAM), Read Only Memory (ROM), variants thereof, combinations thereof, or similar technologies. In specific embodiments, the memory and processor may be integrated into a common device, such as a microprocessor with integrated memory. Additionally, or alternatively, the processing circuitry may comprise hardware components, such as an application-specific integrated circuit (ASIC). Other non-limiting examples of processing circuitry include Integrated Circuit (IC) chips, CPUs, GPUs, microprocessors, Field Programmable Gate Arrays (FPGAs), collections of logic gates or transistors, resistors, capacitors, inductors, and diodes. Some or all of the processing circuitry may be provided on a Printed Circuit Board (PCB) or a collection of PCBs. It should be appreciated that any appropriate type of electrical component or collection of electrical components may be suitable for inclusion in the processing circuitry.

In addition, although not explicitly shown, the present disclosure contemplates that the datacenter 2102 and network device(s) 2106 may include one or more communication interfaces for facilitating wired and/or wireless communication between one another and other unillustrated elements of the network architecture 2100. These communication interfaces may include a variety of technologies, including but not limited to Ethernet ports, fiber optic connections, Wi-Fi® transceivers, Bluetooth® modules, and cellular communication modules for integration and interoperability among the various components within the network architecture 2100.

Furthermore, the present disclosure contemplates that the network architecture 2100 may include additional components and functionalities. For example, the network architecture may include, without limitation, additional processing units, specialized accelerators (such as Tensor Processing Units or TPUs), enhanced security modules, and redundant power supplies. The inclusion of these elements may be intended to ensure that the network architecture 2100 is robust, scalable, and capable of meeting diverse operational requirements. Any variations, modifications, or adaptations of the described elements that fall within the spirit and scope of the disclosure are considered to be encompassed by the present disclosure. This includes any combinations, sub-combinations, or enhancements of the various described elements to achieve improved performance, reliability, and efficiency in the network architecture 2100.

In high-capacity datacenter networks, such as those illustrated in FIGS. 21A-21B, the communication network 2104 may leverage optical transceivers that transmit and receive optical signals over optical fibers or other optical communication mediums in order to establish connection between devices in the architecture 2100.

In at least one example embodiment, the datacenter 2102 corresponds to a collection of network devices, such as network switches (e.g., Ethernet switches, IP routers, multiservice platforms, various transmission network elements, legacy communication equipment, or in any other suitable communication system) connected with a collection of servers or compute nodes.

A switch fabric serves to transfer the data between the switch ports. A switch fabric comprises one or more interconnect circuits, which may be arranged in various switch fabric architectures, e.g., m*m crossbar, Banyan, Benes, Omega, Clos, multi-plane, STS, TST, shared memory, buffered crossbar, any other suitable blocking or non-blocking architecture, or any applicable mixed architecture thereof. A switch fabric is realized in typical embodiments by hardware, which may comprise Field-Programmable Gate Arrays (FPGAs) and/or Application-Specific Integrated Circuits (ASICs), and in some implementations also bus interconnects. The datacenter 2102 may adhere to a networking topology (e.g., a hierarchal networking topology), such as a fat tree topology, a Slim Fly topology, a Dragonfly topology, and/or the like. The datacenter 2102 routes traffic amongst the network switches and servers therein, and at least one layer of the topology in the datacenter 2102 is coupled to the communication network 2104 to allow networking traffic to flow between the datacenter 2102 and the network device(s) 2106.

The communication network 2104 may communicably couple the datacenter 2102 with network device(s) 2106 and other external devices for data exchange and connectivity. Examples of the communication network 2104 may include an Internet Protocol (IP) network, an Ethernet network, an InfiniBand (IB) network, a Fibre Channel network, the Internet, a cellular communication network, a wireless communication network, combinations thereof (e.g., Fibre Channel over Ethernet), variants thereof, and/or the like.

Each type of network offers specific advantages tailored to different operational requirements. For instance, an IP network or Ethernet network may provide widespread compatibility and ease of integration, supporting various protocols and applications across the datacenter and the network device(s) (and/or external devices). An InfiniBand network may offer high throughput and low latency, ideal for HPC environments where rapid data transfer and minimal delay are required. Fibre Channel networks may be employed for their robust performance in storage area networks (SANs), ensuring fast and reliable access to storage resources. Cellular and wireless communication networks may be used to extend connectivity to remote or mobile devices for increased flexibility and accessibility.

FIG. 22 is an example of a system 2200 that includes a device 2210, and communications network 2208, and a device 2212. In one specific but non-limiting example, the communication network 2208 is a network that enables data transmission between the devices 2210 and 2212 using data signals (e.g., digital, optical, wireless signals). In the example of FIG. 22, the device 2210 includes a digital data source 2220, a transmitter 2202, processing circuitry 2232, and a receiver 2204. The communications network 2208 includes a channel 2209, and the device 2212 includes a transceiver 2236 with a receiver 2204.

Examples of the communication network 2208 that may be used to connect a datacenter and the network device(s) 2212 include an Internet Protocol (IP) network, an Ethernet network, an InfiniBand (TB) network, a Fibre Channel network, the Internet, a cellular communication network, a wireless communication network, combinations thereof (e.g., Fibre Channel over Ethernet), variants thereof, and/or the like.

The network device(s) 2210 and 2212 may include a variety of computing devices capable of sending and receiving signals over the communication network 108. The network device(s) can range from personal computing devices to complex server configurations. Examples include Personal Computers (PCs), laptops, tablets, smartphones, and servers. The network device(s) may facilitate user interactions with the datacenter, allowing for data input, retrieval, and processing from remote locations. In addition to individual computing devices, the network device(s) may also include collections of servers or additional datacenters. For instance, these could be other datacenters similar to or the same as datacenter. Such an interconnection may allow for the formation of a distributed computing environment for improved redundancy, load balancing, and disaster recovery capabilities. By linking multiple datacenters, the data center environment 100 can leverage geographically dispersed resources, optimizing performance and ensuring high availability.

The one or more network devices 2210 and 2212 may include one or more of Personal Computer (PC), a laptop, a tablet, a smartphone, a server, a collection of servers, and/or any suitable computing device for sending and receiving signals over the communication network 2208. In at least one example embodiment, the one or more network devices correspond to another datacenter, similar to or the same as datacenter.

As noted above, the datacenter and/or the network device(s) may include storage devices and/or processing circuitry for carrying out computing tasks, for example, tasks associated with controlling the flow of data internally and/or over the communication network. Such processing circuitry may comprise software, hardware, or a combination thereof. For example, the processing circuitry may include a memory including executable instructions and a processor (e.g., a microprocessor) that executes the instructions on the memory. The memory may correspond to any suitable type of memory device or collection of memory devices configured to store instructions. Non-limiting examples of suitable memory devices that may be used include Flash memory, Random Access Memory (RAM), Read Only Memory (ROM), variants thereof, combinations thereof, or the like. In some embodiments, the memory and processor may be integrated into a common device (e.g., a microprocessor may include integrated memory). Additionally or alternatively, the processing circuitry may comprise hardware, such as an application specific integrated circuit (ASIC). Other non-limiting examples of the processing circuitry include an Integrated Circuit (IC) chip, a Central Processing Unit (CPU), a Graphics Processing Unit (GPU), a microprocessor, a Field Programmable Gate Array (FPGA), a collection of logic gates or transistors, resistors, capacitors, inductors, diodes, or the like. Some or all of the processing circuitry may be provided on a Printed Circuit Board (PCB) or collection of PCBs. It should be appreciated that any appropriate type of electrical component or collection of electrical components may be suitable for inclusion in the processing circuitry.

In addition, although not explicitly shown, it should be appreciated that the datacenter and network device(s) may include one or more communication interfaces for facilitating wired and/or wireless communication between one another and other unillustrated elements of the data center environment. These communication interfaces may include a variety of technologies, including but not limited to Ethernet ports, fiber optic connections, Wi-Fi® transceivers, Bluetooth® modules, and cellular communication modules for integration and interoperability among the various components within the data center environment. Furthermore, it should be understood that the data center environment may include additional components and functionalities within the scope of the present disclosure. These components may comprise, without limitation, additional processing units, specialized accelerators (such as Tensor Processing Units or TPUs), enhanced security modules, and redundant power supplies. The inclusion of these elements is intended to ensure that the data center environment is robust, scalable, and capable of meeting diverse operational requirements. Any variations, modifications, or adaptations of the described elements that fall within the spirit and scope of the disclosure are considered to be encompassed by the present disclosure. This includes any combinations, sub-combinations, or enhancements of the various described elements to achieve improved performance, reliability, and efficiency in the data center environment 100.

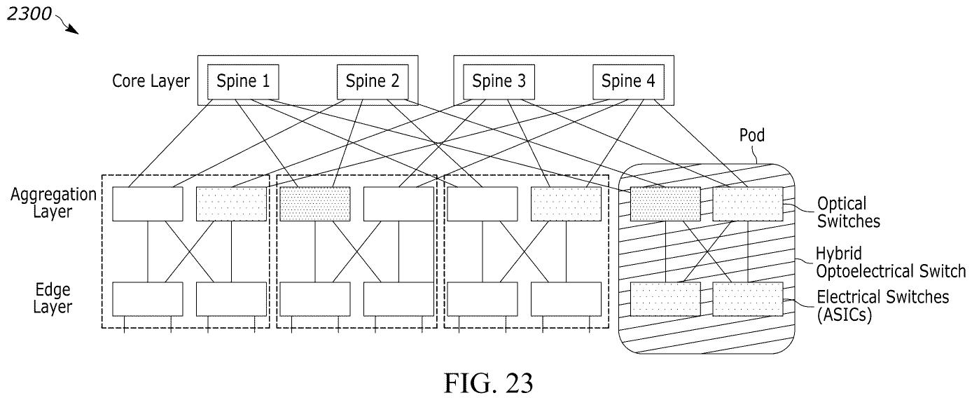

FIG. 23 illustrates a fat tree topology 2300 for a datacenter, in accordance with embodiments of the disclosure. However, it is to be understood that the present disclosure is not limited to a fat tree topology. Other network topologies may also be contemplated within the scope of the disclosure. Examples of such alternative topologies include, but are not limited to, Slim Fly topology, which is designed to reduce the number of hops and cable lengths between nodes; Dragonfly topology, which aims to enhance network scalability and reduce latency through a hierarchical group of interconnected switches; and other hierarchical or non-hierarchical topologies that may be optimized for specific performance, scalability, or cost considerations. The principles and innovations disclosed herein can be applied to these and other network topologies to achieve similar advantages and benefits. Any modifications, variations, or adaptations of the network topologies that fall within the spirit and scope of the present disclosure are considered to be encompassed by this disclosure. In related art systems, a fat tree topology may use the same electrical switching devices on all layers (edge, aggregation, core). For example, each switching device may be 1 U switch, where 1 U refers to the industry standard size for rack-mounted switch and/or server. The interconnection between switches of different layers may be accomplished with optical links using active optical cables and optical transceivers implemented in a pluggable form factor (also referred to as “pluggables”).

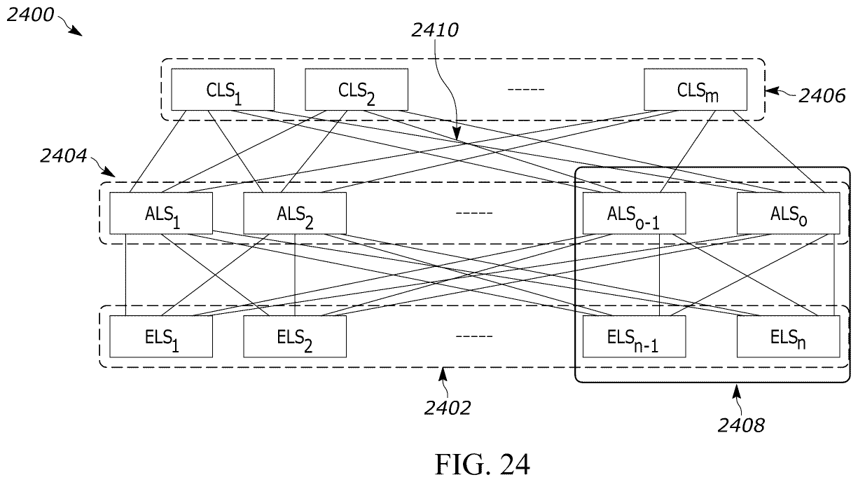

FIG. 24 is an example of a fat tree topology 2400 of a network. As shown in FIG. 24, the fat tree topology may include three distinct layers: the edge layer 2402, the aggregation layer 2404, and the core layer 2406. The edge layer 2402, located at the bottom of the hierarchy, incorporates Top-of-Rack (ToR) switches. The edge layer 2402 may serve as the initial point of aggregation for traffic originating from the servers. The servers and server racks are generally connected to the edge layer 2402, although they are not illustrated in the figure. The edge layer 2402 may include a plurality of switches, designated as ELS1, ELS2, . . . , ELSn, as shown in FIG. 24. The aggregation layer 2404 may be positioned above the edge layer 2402 and may further consolidate traffic from multiple edge layer switches ELS1, ELS2, . . . , ELSn. The aggregation layer 2404 may be composed of switches ALS1, ALS2, . . . , ALSo. The aggregation layer switches may be configured to aggregate data traffic from the edge layer 2402, ensuring efficient load balancing and data flow management. At the top of the hierarchy is the core layer 2406, which may provide high-speed interconnectivity and enables communication among different racks within a datacenter. The core layer 2406 may include a series of switches labeled as CLS1, CLS2, . . . , CLSm. These core layer switches may be configured to ensure that data can traverse the network quickly and efficiently, minimizing latency and maximizing bandwidth.

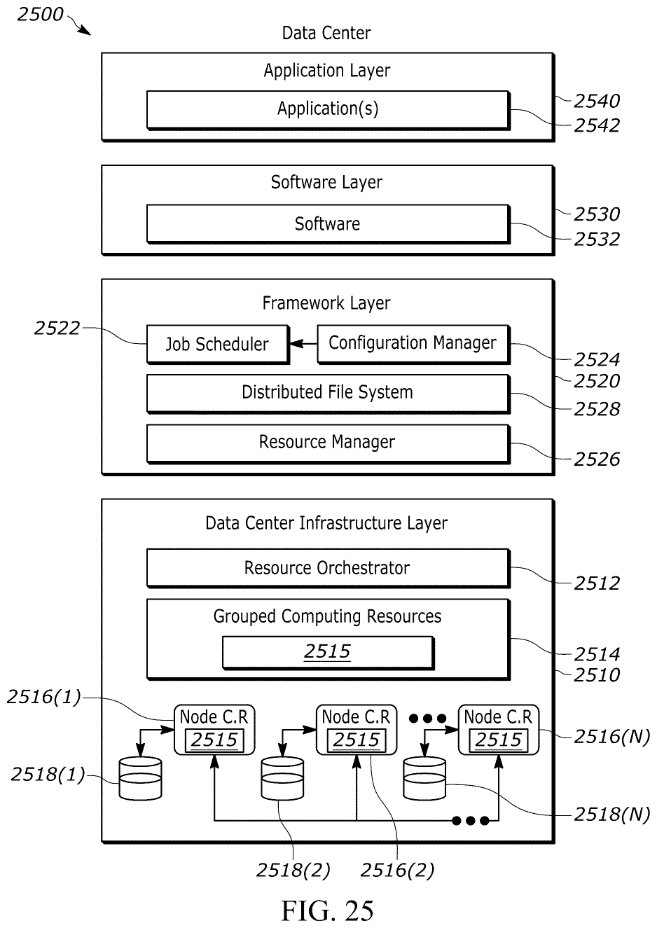

Optical data center networks rely on allocation and deallocation of light paths from the data sources to the destinations end-ports to guarantee no light collisions and data loss occur in the fabric. Traditionally the allocation algorithms are run from a central entity which considers the entire demand for source and destination flows and try to find the most dense mapping of these demands to network resources over a single or multiple time periods. FIG. 25 illustrates an example data center 2500, in which at least one embodiment may be used. In at least one embodiment, data center 2500 includes a data center infrastructure layer 2510, a framework layer 2520, a software layer 2530 and an application layer 2540.

In at least one embodiment, as shown in FIG. 25, data center infrastructure layer 2510 may include a resource orchestrator 2512, grouped computing resources 2514, and node computing resources (“node C.R.s”) 2516(1)-2516(N), where “N” represents a positive integer (which may be a different integer “N” than used in other figures). In at least one embodiment, node C.R.s 2516(1)-2516(N) may include, but are not limited to, any number of central processing units (“CPUs”) or other processors (including accelerators, field programmable gate arrays (FPGAs), graphics processors, etc.), memory storage devices 2518(1)-2518(N) (e.g., dynamic read-only memory, solid state storage or disk drives), network input/output (“NW I/O”) devices, network switches, virtual machines (“VMs”), power modules, and cooling modules, etc. In at least one embodiment, one or more node C.R.s from among node C.R.s 2516(1)-2516(N) may be a server having one or more of above-mentioned computing resources.

In at least one embodiment, grouped computing resources 2514 may include separate groupings of node C.R.s housed within one or more racks (not shown), or many racks housed in data centers at various geographical locations (also not shown). In at least one embodiment, separate groupings of node C.R.s within grouped computing resources 2514 may include grouped compute, network, memory or storage resources that may be configured or allocated to support one or more workloads. In at least one embodiment, several node C.R.s including CPUs or processors may be grouped within one or more racks to provide compute resources to support one or more workloads. In at least one embodiment, one or more racks may also include any number of power modules, cooling modules, and network switches, in any combination.

In at least one embodiment, resource orchestrator 2512 may configure or otherwise control one or more node C.R.s 2516(1)-2516(N) and/or grouped computing resources 2514. In at least one embodiment, resource orchestrator 2512 may include a software design infrastructure (“SDI”) management entity for data center 2500. In at least one embodiment, resource orchestrator 2512 may include hardware, software or some combination thereof.

In at least one embodiment, as shown in FIG. 25, framework layer 2520 includes a job scheduler 2522, a configuration manager 2524, a resource manager 2526 and a distributed file system 2528. In at least one embodiment, framework layer 2520 may include a framework to support software 2532 of software layer 2530 and/or one or more application(s) 2542 of application layer 2540. In at least one embodiment, software 2532 or application(s) 2542 may respectively include web-based service software or applications, such as those provided by Amazon Web Services, Google Cloud and Microsoft Azure. In at least one embodiment, framework layer 2520 may be, but is not limited to, a type of free and open-source software web application framework such as Apache Spark™ (hereinafter “Spark”) that may use distributed file system 2528 for large-scale data processing (e.g., “big data”). In at least one embodiment, job scheduler 2522 may include a Spark driver to facilitate scheduling of workloads supported by various layers of data center 2500. In at least one embodiment, configuration manager 2524 may be capable of configuring different layers such as software layer 2530 and framework layer 2520 including Spark and distributed file system 2528 for supporting large-scale data processing. In at least one embodiment, resource manager 2526 may be capable of managing clustered or grouped computing resources mapped to or allocated for support of distributed file system 2528 and job scheduler 2522. In at least one embodiment, clustered or grouped computing resources may include grouped computing resources 2514 at data center infrastructure layer 2510. In at least one embodiment, resource manager 2526 may coordinate with resource orchestrator 2512 to manage these mapped or allocated computing resources.

In at least one embodiment, software 2532 included in software layer 2530 may include software used by at least portions of node C.R.s 2516(1)-2516(N), grouped computing resources 2514, and/or distributed file system 2528 of framework layer 2520. In at least one embodiment, one or more types of software may include, but are not limited to, Internet web page search software, e-mail virus scan software, database software, and streaming video content software.

In at least one embodiment, application(s) 2542 included in application layer 2540 may include one or more types of applications used by at least portions of node C.R.s 2516(1)-2516(N), grouped computing resources 2514, and/or distributed file system 2528 of framework layer 2520. In at least one embodiment, one or more types of applications may include, but are not limited to, any number of a genomics application, a cognitive compute, application and a machine learning application, including training or inferencing software, machine learning framework software (e.g., PyTorch, TensorFlow, Caffe, etc.) or other machine learning applications used in conjunction with one or more embodiments.

In at least one embodiment, any of configuration manager 2524, resource manager 2526, and resource orchestrator 2512 may implement any number and type of self-modifying actions based on any amount and type of data acquired in any technically feasible fashion. In at least one embodiment, self-modifying actions may relieve a data center operator of data center 2500 from making possibly bad configuration decisions and possibly avoiding underused and/or poor performing portions of a data center.

In at least one embodiment, data center 2500 may include tools, services, software or other resources to train one or more machine learning models or predict or infer information using one or more machine learning models according to one or more embodiments described herein. For example, in at least one embodiment, a machine learning model may be trained by calculating weight parameters according to a neural network architecture using software and computing resources described above with respect to data center 2500. In at least one embodiment, trained machine learning models corresponding to one or more neural networks may be used to infer or predict information using resources described above with respect to data center 2500 by using weight parameters calculated through one or more training techniques described herein.

A photonic neural network (PNN) system may include a number of optical interconnect structures. The optical interconnect structure may be configured to transmit/receive an optical signal (e.g., light), and direct or otherwise guide the optical signal via optical waveguides from/to one or more optical devices (e.g., modulators and photodetectors). In some scenarios, these optical waveguides may be formed in a single level. In consideration of saving a total area occupied by the corresponding photonic die, such optical waveguides may be formed (e.g., stacked) across multiple levels. When being stacked, each of the waveguides typically has a certain portion vertically overlapped with (a portion) of a neighboring waveguide. Each of the waveguides may be formed as having a transitioning portion interposed between two tapered portions to optically communicate with each other and assure the optical signal propagated therein can be saturated.

In at least one embodiment, data center may use CPUs, application-specific integrated circuits (ASICs), GPUs, FPGAs, or other hardware to perform training and/or inferencing using above-described resources. Moreover, one or more software and/or hardware resources described above may be configured as a service to allow users to train or performing inferencing of information, such as image recognition, speech recognition, or other artificial intelligence services.

Inference and/or training logic 2515 are used to perform inferencing and/or training operations associated with one or more embodiments. In at least one embodiment, inference and/or training logic 2515 may be used in system FIG. 25 for inferencing or predicting operations based, at least in part, on weight parameters calculated using neural network training operations, neural network functions and/or architectures, or neural network use cases described herein.

In at least one embodiment, an artificial intelligence (AI) data center infrastructure platform is provided. Examples of an AI data center infrastructure platform are Nvidia® DGX™ SuperPOD™ and DGX™ Foundry. In at least one embodiment, an AI data center infrastructure platform provides accelerated infrastructure and/or scalable performance tailored for AI such as machine learning (ML) and other high-performance computing (HPC) loads.

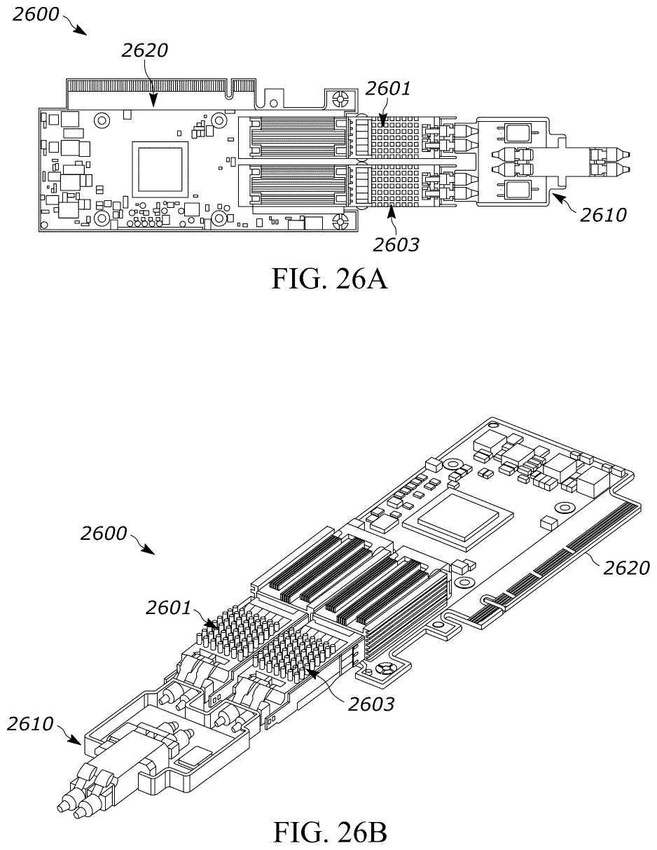

FIGS. 26A and 26B illustrate a top view and a perspective view, respectively, of a transceiver module operatively coupled to a network adapter, in the present example a Network Interface Controller (NIC) 2600, in accordance with an embodiment of the disclosure. As shown in FIGS. 26A and 26B, the transceiver module may include a first optical module 2601, a second optical module 2603, an adapter 2610, and a dual-port NIC 2620 of a server. Both the first optical module 2601 and the second optical module 2603 may be dual-fiber transceivers that are configured for duplex communication that allows the source (e.g., server) to communicate with the target (e.g., leaf switch) in both directions. The adapter 2610 may be a ganged physical component configured to link the first optical module 2601 and the second optical module 2603 for the purpose of transmitting and receiving data to and from the leaf switch.

In some embodiments, the adapter 2610 may be configured to operate in two configurations, such as a first configuration and a second configuration. In one aspect, the first configuration may be a default configuration of operation, where the first optical module 2601 may be operationally active. The second configuration may be a contingent configuration that is implemented when the first optical module 2601 operationally fails. When such a failure is detected, the second optical module 2603, which is otherwise operationally inactive or idle, may be engaged become operationally active and handle all network traffic that was initially handled by the first optical module 2601.

In some embodiments, the transceiver module 2600 may be configured to operate in a leaf-spine architecture. A leaf-spine architecture is a data center network topology that may include two switching layers—a spine layer and a leaf layer. The leaf layer may include access switches (leaf switches) that aggregate traffic from servers and connect directly into the spine or network core. Spine switches interconnect all leaf switches in a full-mesh topology between access switches in the leaf layer and the servers from which the access switches aggregate traffic. As such, in one embodiment, to ensure reliable operation of downlinks, the transceiver module 2600 may be configured to operate between the server and the leaf layer. In particular, as shown in FIGS. 26A and 26B, the adapter 2610 may be operatively coupled to the first optical module 2601 and the second optical module 2603, while the first optical module 2601 and the second optical module 2603 may be operatively coupled to a dual-port NIC 2620 of a server.

In embodiments, NIC 2600 may comprise one or more processing circuits, as detailed above; the processing circuits may comprise FW, that is loaded according to the techniques described above.

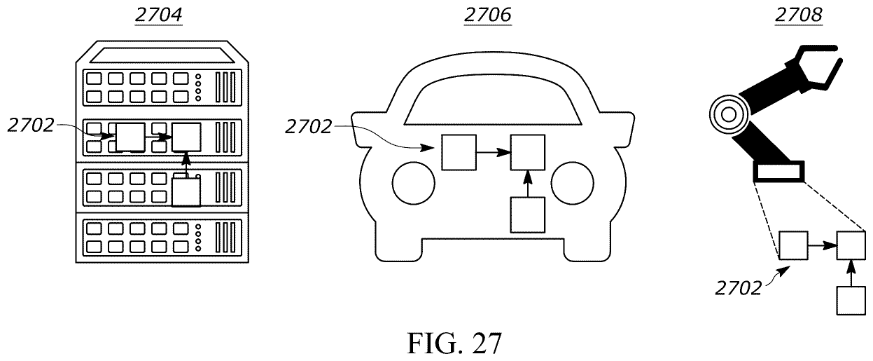

FIG. 27 depicts exemplary scenarios for use of an optical transceiver 2702 in accordance with some embodiments. An optical transceiver 2702 may be utilized in a computing system 2704 (e.g., in a server farm, or within a server computer system), a vehicle 2706 (e.g., a car, truck, train, or airplane), and a robot 2708 (or among robots in a factory), to name just a few examples. The optical transceiver 2702 may be particularly useful for high-speed communication in environments subject to high levels of electromagnetic interference (EMI).

System Overview: The systems and methods described herein may be implemented across a range of data center and high-performance computing environments. In some embodiments, components may include one or more optical transceivers, photonic integrated circuits (PICs), electronic processors, memory units, and programmable logic (e.g., FPGAs or ASICs).

The system architecture may include a layered protocol stack enabling optical interconnects between compute nodes, GPUs, or switch fabrics. Although described in the context of optical signaling (e.g., PAM4 modulation over silicon photonics), the methods may be adapted for use in electrical signaling environments or hybrid opto-electrical systems.

Hardware/Software Flexibility: Aspects of the disclosed technology may be implemented in hardware, software, firmware, or combinations thereof. For example, a congestion-aware routing module may be realized as a hardware IP block, or as software instructions executing on a network controller.

The system may include machine-readable instructions stored in non-transitory memory that, when executed, cause the system to perform steps such as: dynamic wavelength assignment, error correction encoding, channel bonding, or adaptive modulation format selection.

Modularity & Scalability: In some implementations, system components may be distributed across multiple dies or chiplets interconnected via high-speed SerDes lanes, optical waveguides, or interposer-based photonic links. Embodiments may support scaling from single-link configurations to mesh, torus, or custom topologies based on application workload requirements.

Terminology: As used herein, terms like “transmit unit,” “controller,” “interconnect fabric,” or “node” are not limited to any specific implementation, and may encompass hardware, virtualized, or software-defined instances depending on deployment context.

Although specific embodiments of the disclosure have been described and illustrated, the disclosure is not to be limited to the specific forms or arrangements of parts so described and illustrated. The scope of the disclosure is to be defined by the claims appended hereto and their equivalents.

What is claimed is:

1. A pluggable electronic module comprising:
a housing having a front end and a back end, wherein the back end of the housing includes a sloped leading edge with a channel in a central region of the sloped leading edge.

2. The pluggable electronic module of claim 1, wherein the channel is configured to reduce contact with a thermal interface material (TIM) during insertion of the pluggable electronic module into a cage.

3. The pluggable electronic module of claim 1, wherein the channel is configured to reduce contact with a thermal interface material (TIM) at high-pressure points during insertion of the pluggable electronic module into a cage to reduce the risk of puncture and tearing of the TIM, wherein the TIM covers a portion of a heatsink.

4. The pluggable electronic module of claim 1, wherein the channel is configured to reduce contact with a thermal interface material (TIM) at high-pressure points during insertion of the pluggable electronic module into a cage, and wherein rails of the housing act to resist a spring mechanism of a heatsink, ensuring that the heatsink aligns properly within a cage.

5. The pluggable electronic module of claim 1, wherein the channel is configured to reduce contact with a thermal interface material (TIM) during insertion of the pluggable electronic module into a cage, wherein the TIM covers a portion of a heatsink.

6. The pluggable electronic module of claim 1, wherein opposite sides of the channel are defined by rails that are elevated relative to a bottom surface of the channel.

7. The pluggable electronic module of claim 1, wherein the housing has a width dimension, and the channel has a width dimension that is in the range of 40-90% of the width dimension of the housing.

8. The pluggable electronic module of claim 1, wherein the sloped leading edge at the back end of the housing has a rounded shape.

9. The pluggable electronic module of claim 1, wherein the sloped leading edge is at a top side of the back end of the housing.

10. The pluggable electronic module of claim 1, wherein the channel has a slope that matches a slope of the sloped leading edge at the back end of the housing.

11. The pluggable electronic module of claim 1, wherein the sloped leading edge at the back end of the housing has a rounded shape, and wherein the channel has a rounded shape that matches a rounded shape of the sloped leading edge at the back end of the housing.

12. The pluggable electronic module of claim 1, wherein the channel runs parallel to a centerline of the housing.

13. The pluggable electronic module of claim 1, wherein the housing is an elongated structure, and wherein the channel runs parallel to a centerline of the elongated structure.

14. The pluggable electronic module of claim 1, wherein the pluggable electronic module includes a communications circuit within the housing, the communications circuit including a cable connector at the front end of the housing and a printed circuit board (PCB) interface at the back end of the housing.

15. The pluggable electronic module of claim 1, wherein the pluggable electronic module is an optical transceiver that includes a communications circuit within the housing, the communications circuit including a cable connector at the front end of the housing and a PCB interface at the back end of the housing.

16. A pluggable electronic module comprising:
a housing having a front end and a back end;
a cable connector at the front end of the housing; and
a sloped leading edge at the back end of the housing, wherein the sloped leading edge at the back end of the housing includes a channel in a central region of the sloped leading edge.

17. The pluggable electronic module of claim 16, wherein the channel is configured to reduce contact with a thermal interface material (TIM) during insertion of the pluggable electronic module into a cage.

18. The pluggable electronic module of claim 16, wherein the pluggable electronic module includes a communications circuit within the housing, the communications circuit including the cable connector at the front end of the housing and a printed circuit board (PCB) interface at the back end of the housing.

19. The pluggable electronic module of claim 16, wherein:
the pluggable electronic module includes a communications circuit within the housing, the communications circuit including the cable connector at the front end of the housing and a printed circuit board (PCB) interface at the back end of the housing; and
the channel is configured to reduce contact with a thermal interface material (TIM) during insertion of the pluggable electronic module into a cage.

20. A pluggable electronic module comprising:
a housing having a front end and a back end; and
a communications circuit within the housing, the communications circuit including a cable connector at the front end of the housing and a printed circuit board (PCB) interface at the back end of the housing;
wherein the back end of the housing includes a sloped leading edge, wherein the sloped leading edge at the back end of the housing includes a channel in a central region of the sloped leading edge.
